(19) United States
(12) Patent Application Publication
(10) Pub. No.: US 2026/0101740 A1
(43) Pub. Date: Apr. 9, 2026

(54) SEMICONDUCTOR PACKAGE

(71) Applicant: Samsung Electronics Co., Ltd., Suwon-si (KR)

(72) Inventor: Donghun Lee, Suwon-si (KR)

(21) Appl. No.: 19/330,490

(22) Filed: Sep. 16, 2025

(30) Foreign Application Priority Data
Oct. 8, 2024 (KR) 10-2024-0136823

(51) Int. Cl. H01L 23/48; H01L 23/00; H01L 23/31; H01L 25/04

(52) U.S. Cl. CPC H10W 20/20; H10W 74/141; H10W 90/00; H10W 90/792

(57) ABSTRACT

A semiconductor package includes a first semiconductor chip and a plurality of first through-electrodes passing through the first semiconductor substrate, a plurality of second semiconductor chips each including a second semiconductor substrate and a plurality of second through-electrodes passing through the second semiconductor substrate, the plurality of second semiconductor chips being stacked on the first semiconductor chip, a plurality of bonding pads disposed between the first semiconductor chip and the plurality of second semiconductor chips and electrically connecting the plurality of first through-electrodes to the plurality of second through-electrodes, a dummy chip attached to the plurality of second semiconductor chips, and, a package molding layer on the first semiconductor chip covering the first semiconductor chip, the plurality of second semiconductor chips, and the dummy chip, in which the dummy chip includes a plurality of trenches filled by a portion of the package molding layer.

### CROSS-REFERENCE TO RELATED APPLICATIONS

This application claims priority to Korean Patent Application No. 10-2024-0136823, filed in the Korean Intellectual Property Office on October 8, 2024, the disclosure of which is incorporated by reference herein in its entirety.

### BACKGROUND

As small-sized, large-capacity, and high-performance electronic products are needed, there is a need to increase the degree of integration and the speed of semiconductor packages. To this end, semiconductor packages including stacked semiconductor chips are being developed.

### SUMMARY

In general, the present disclosure is directed toward a semiconductor package having a reliable structure.

According to some implementations, the present disclosure is directed to a semiconductor package that includes a first semiconductor chip including a first semiconductor substrate and a plurality of first through-electrodes passing through the first semiconductor substrate, the first semiconductor substrate including a first active surface and a first inactive surface opposite to the first active surface, a plurality of second semiconductor chips, each second semiconductor chip of the plurality of second semiconductor chips including a second semiconductor substrate, a plurality of second through-electrodes passing through the second semiconductor substrate, the second semiconductor substrate including a second active surface and a second inactive surface opposite to the second active surface, the second active surface of the second semiconductor substrate facing the first inactive surface of the first semiconductor substrate, and the plurality of second semiconductor chips being stacked on the first semiconductor chip, a plurality of bonding pads between the first semiconductor chip and the plurality of second semiconductor chips, the plurality of bonding pads electrically connecting the plurality of first through-electrodes to the plurality of second through-electrodes, a dummy chip including a dummy substrate having a substrate top surface and a substrate bottom surface opposite to the substrate top surface, the substrate bottom surface of the dummy substrate facing an uppermost second semiconductor chip of the plurality of second semiconductor chips, and the dummy chip being attached to the plurality of second semiconductor chips, and a package molding layer on the first semiconductor chip and covering an upper surface of the first semiconductor chip, side surfaces of the plurality of second semiconductor chips, and a side surface of the dummy chip, wherein the dummy chip comprises a plurality of trenches receiving a filling molding portion of the package molding layer and extending into the dummy substrate from a lower surface of the dummy chip.

According to some implementations, the present disclosure is directed to a semiconductor package that includes a first semiconductor chip including a first semiconductor substrate having a first active surface and a first inactive surface opposite to the first active surface, a plurality of first through-electrodes passing through the first semiconductor substrate, a plurality of package connection pads connected to the plurality of first through-electrodes on the first active surface of the first semiconductor substrate, a first front insulation layer surrounding the plurality of package connection pads on the first active surface of the first semiconductor substrate, and a first backside insulation layer covering the first inactive surface of the first semiconductor substrate, a plurality of second semiconductor chips, each second semiconductor chip of the plurality of second semiconductor chips including a second semiconductor substrate having a second active surface and a second inactive surface opposite to the second active surface, a plurality of second through-electrodes passing through the second semiconductor substrate, a second front insulation layer on the second active surface of the second semiconductor substrate, and a second backside insulation layer covering the second inactive surface of the second semiconductor substrate, the second active surface of the second semiconductor substrate facing the first inactive surface of the first semiconductor substrate, and the plurality of second semiconductor chips being stacked on the first semiconductor chip, a plurality of first bonding pads between the first semiconductor chip and a lowermost second semiconductor chip of the plurality of second semiconductor chips, the plurality of first bonding pads electrically connecting the plurality of first through-electrodes of the first semiconductor chip to the plurality of second through-electrodes of the lowermost second semiconductor chip, the plurality of first bonding pads passing through the first backside insulation layer of the first semiconductor chip and the second front insulation layer of the lowermost second semiconductor chip of the plurality of second semiconductor chips, a plurality of second bonding pads between two second semiconductor chips of the plurality of second semiconductor chips, the two second semiconductor chips being adjacent to each other in a vertical direction, the plurality of second bonding pads electrically connecting the plurality of second through-electrodes of each of the plurality of second through-electrodes of the two second semiconductor chips, the plurality of second bonding pads passing through a second backside insulation layer of a lower second semiconductor chip and a second front insulation layer of an upper second semiconductor chip among the two second semiconductor chips adjacent to each other in the vertical direction, a dummy chip including a dummy substrate having a substrate top surface and a substrate bottom surface opposite to the substrate top surface, the substrate bottom surface of the dummy substrate facing an uppermost second semiconductor chip of the plurality of second semiconductor chips, and the dummy chip being attached to the plurality of second semiconductor chips, and a package molding layer on the first semiconductor chip, the package molding layer covering an upper surface of the first semiconductor chip, side surfaces of the plurality of second semiconductor chips, and a side surface of the dummy chip, wherein the dummy chip comprises a plurality of trenches receiving a filling molding portion of the package molding layer, the plurality of trenches extending into the dummy substrate from a side surface of the dummy chip and extending into the dummy substrate from a lower surface of the dummy chip.

a first semiconductor chip including a first semiconductor substrate having a first active surface and a first inactive surface opposite to the first active surface, a plurality of first through-electrodes passing through the first semiconductor substrate, a plurality of package connection pads connected to the plurality of first through-electrodes on the first active surface of the first semiconductor substrate, a first front insulation layer surrounding the plurality of package connection pads on the first active surface of the first semiconductor substrate, and a first backside insulation layer covering the first inactive surface of the first semiconductor substrate, a plurality of second semiconductor chips, each second semiconductor chip of the plurality of second semiconductor chips includes a second semiconductor substrate having a second active surface and a second inactive surface opposite to the second active surface, a plurality of second through-electrodes passing through the second semiconductor substrate, a second front insulation layer on the second active surface of the second semiconductor substrate, and a second backside insulation layer covering the second inactive surface of the second semiconductor substrate, the second active surface of the second semiconductor substrate facing the first inactive surface of the first semiconductor substrate, and the plurality of second semiconductor chips being stacked on the first semiconductor chip, a plurality of first bonding pads between the first semiconductor chip and a lowermost second semiconductor chip of the plurality of second semiconductor chips, the plurality of first bonding pads electrically connecting the plurality of first through-electrodes of the first semiconductor chip to the plurality of second through-electrodes of the lowermost second semiconductor chip, the plurality of first bonding pads passing through the first backside insulation layer of the first semiconductor chip and the second front insulation layer of the lowermost second semiconductor chip of the plurality of second semiconductor chips, a plurality of second bonding pads between two second semiconductor chips of the plurality of second semiconductor chips, the two second semiconductor chips being adjacent to each other in a vertical direction, the plurality of second bonding pads electrically connecting the plurality of second through-electrodes of each of the plurality of second through-electrodes of the two second semiconductor chips, the plurality of second bonding pads passing through a second backside insulation layer of a lower second semiconductor chip and a second front insulation layer of an upper second semiconductor chip of the two second semiconductor chips adjacent to each other in the vertical direction, a dummy chip including a dummy substrate having a substrate top surface and a substrate bottom surface opposite to the substrate top surface and a bonding insulation layer covering the substrate bottom surface of the dummy substrate, the bonding insulation layer facing an uppermost second semiconductor chip of the plurality of second semiconductor chips and being attached to the plurality of second semiconductor chips, and a package molding layer on the first semiconductor chip, the package molding layer covering an upper surface of the first semiconductor chip, side surfaces of the plurality of second semiconductor chips, and a side surface of the dummy chip, wherein the dummy chip comprises a plurality of trenches receiving a filling molding portion of the package molding layer, the plurality of trenches extending from a first side surface of the dummy chip to a second side surface of the dummy chip, and passing through the substrate bottom surface of the dummy substrate from a lower surface of the bonding insulation layer and extending into the dummy substrate.

### BRIEF DESCRIPTION OF THE DRAWINGS

Example implementations will be more clearly understood from the following detailed description, taken in conjunction with the accompanying drawings.

FIG. 1 is a cross-sectional view illustrating an example of a semiconductor package according to some implementations.

FIGS. 2A to 2D are plan views illustrating an example of a dummy chip included in a semiconductor package according to some implementations.

FIGS. 3A to 3L are cross-sectional views illustrating stage-by-stage an example of a method of manufacturing a semiconductor package according to some implementations.

FIG. 4 is a cross-sectional view illustrating an example of a semiconductor package according to some implementations.

FIGS. 5A and 5B are cross-sectional views illustrating an example of a semiconductor package according to some implementations.

FIGS. 6A and 6B are cross-sectional views illustrating an example of a semiconductor package according to some implementations.

FIGS. 7A and 7B are cross-sectional views illustrating an example of a semiconductor package according to some implementations.

### DETAILED DESCRIPTION

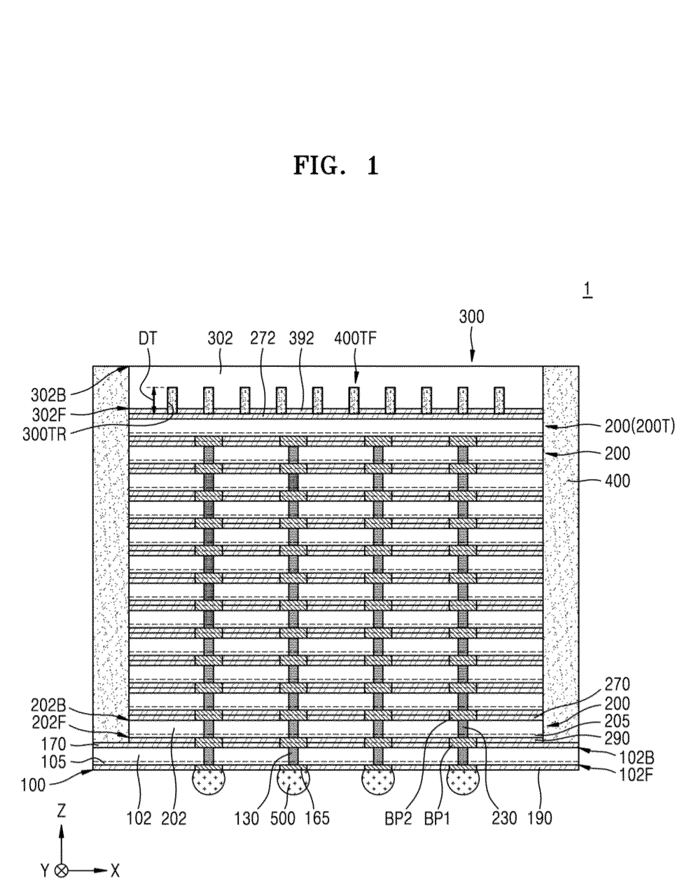

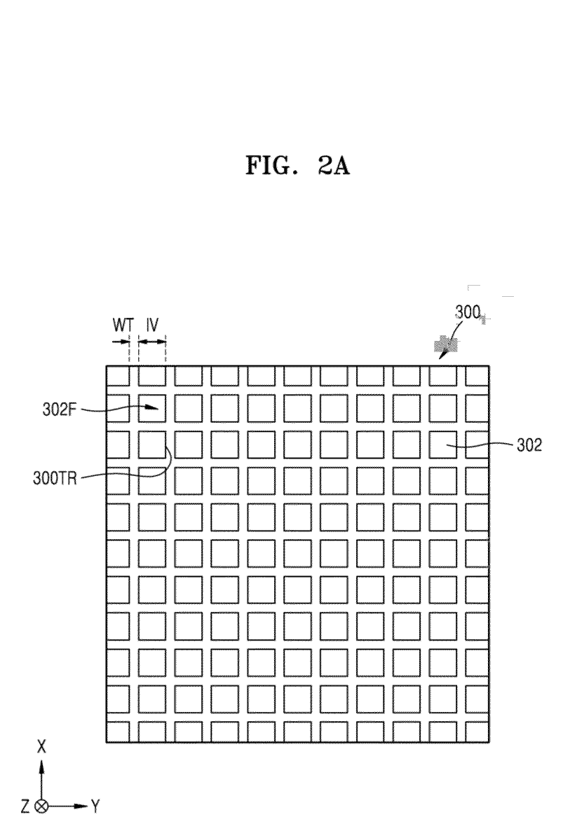

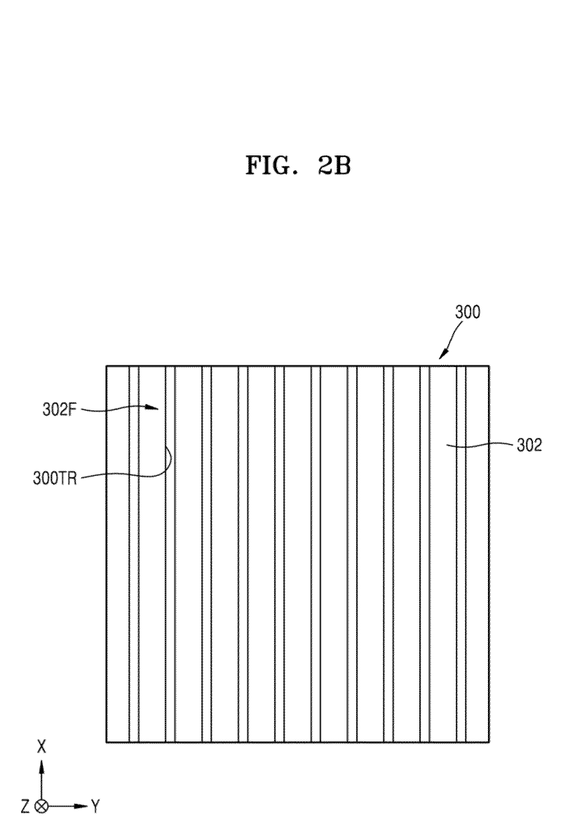

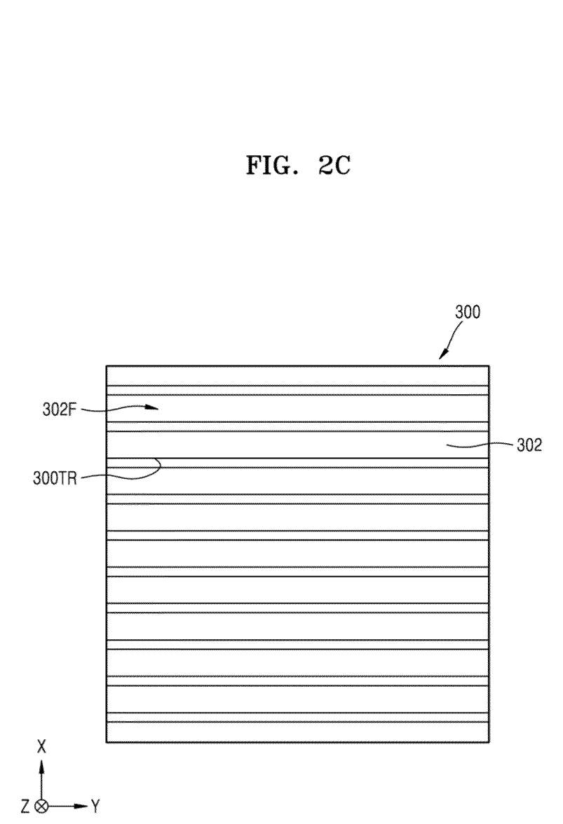

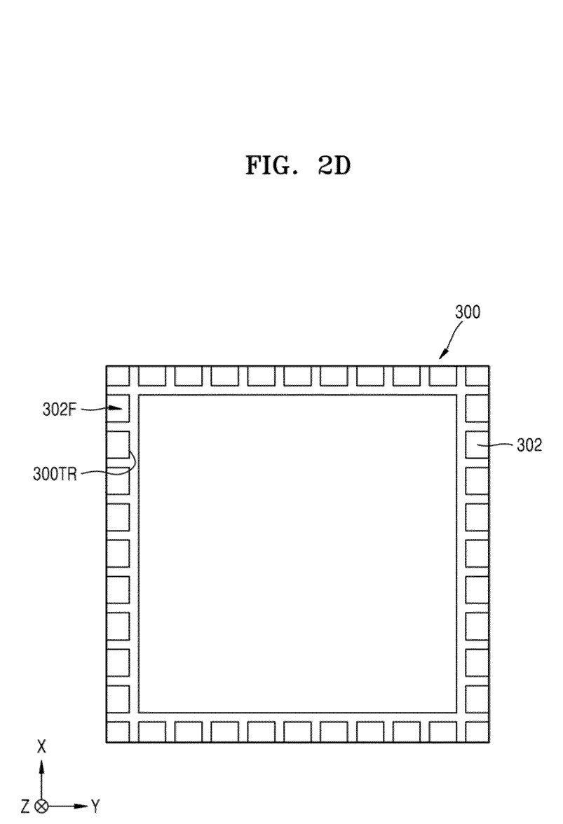

FIG. 1 is a cross-sectional view illustrating an example of a semiconductor package according to some implementations, and FIGS. 2A to 2D are plan views illustrating an example of a dummy chip included in a semiconductor package according to some implementations. In detail, each of FIGS. 2A to 2D is a plan view of a dummy substrate of a dummy chip as seen upward from below.

In FIG. 1, a semiconductor package 1 may include a first semiconductor chip 100, a plurality of second semiconductor chips 200, and a dummy chip 300. In FIG. 1, the semiconductor package 1 is illustrated as including twelve second semiconductor chips 200, but the present disclosure is not limited thereto. For example, the semiconductor package 1 may include two or more second semiconductor chips 200. In some implementations, the semiconductor package 1 may include a 4-multiple number of second semiconductor chips 200. For example, the semiconductor package 1 may include four second semiconductor chips 200, eight second semiconductor chips 200, twelve second semiconductor chips 200, or sixteen second semiconductor chips 200. A plurality of second semiconductor chips 200 may be sequentially stacked in a vertical direction (a Z direction) on the first semiconductor chip 100. An uppermost second semiconductor chip 200 of the plurality of second semiconductor chips 200 may be referred to as an uppermost second semiconductor chip 200T.

The first semiconductor chip 100 and the plurality of second semiconductor chips 200 each included in the semiconductor package 1 may be electrically connected to each other through a plurality of first bonding pads BP1 and a plurality of second bonding pads BP2, may transfer and receive a signal therebetween, and may provide power and a ground. For example, the plurality of first bonding pads BP1 may be disposed between the first semiconductor chip 100 and a lowermost second semiconductor chip 200 of the plurality of second semiconductor chips 200, and each of the plurality of second bonding pads BP2 may be disposed between two second semiconductor chips 200 adjacent to each other in the vertical direction (the Z direction) among the plurality of second semiconductor chips 200. The plurality of first bonding pads BP1 and the plurality of second bonding pads BP2 may be referred to as a plurality of bonding pads.

The first semiconductor chip 100 may include a first semiconductor substrate 102 including a first active surface 102F and a first inactive surface 102B opposite to each other, a first semiconductor device 105 disposed on the first active surface 102F of the first semiconductor substrate 102, a plurality of first through-electrodes 130 passing through at least a portion of the first semiconductor substrate 102, a plurality of first front chip connection pads 165 electrically connected to the plurality of first through-electrodes 130 on the first active surface 102F of the first semiconductor substrate 102, a first front insulation layer 190 surrounding the plurality of first front chip connection pads 165 on the first active surface 102F of the first semiconductor substrate 102, and a first backside insulation layer 170 covering the first inactive surface 102B of the first semiconductor substrate 102. The plurality of first front chip connection pads 165 may be referred to as a plurality of package connection pads.

The first backside insulation layer 170 may surround partial portions of the plurality of first bonding pads BP1 disposed between the first semiconductor chip 100 and the lowermost second semiconductor chip 200 of the plurality of second semiconductor chips 200. For example, the first backside insulation layer 170 may surround lower portions of the plurality of first bonding pads BP1.

A plurality of package connection terminals 500 may be attached to the plurality of first front chip connection pads 165. For example, each of the plurality of package connection terminals 500 may be a solder ball or a bump. The plurality of package connection terminals 500 may electrically connect the semiconductor package 1 to an external device.

The second semiconductor chip 200 may include a second semiconductor substrate 202 including a second active surface 202F and a second inactive surface 202B opposite to each other, a second semiconductor device 205 disposed on the second active surface 202F of the second semiconductor substrate 202, a plurality of second through-electrodes 230 passing through at least a portion of the second semiconductor substrate 202, a second front insulation layer 290 covering the second active surface 202F of the second semiconductor substrate 202, and a second backside insulation layer 270 covering the second inactive surface 202B of the second semiconductor substrate 202.

The second front insulation layer 290 may surround partial portions of the plurality of first bonding pads BP1 disposed between the first semiconductor chip 100 and the lowermost second semiconductor chip 200 of the plurality of second semiconductor chips 200 or partial portions of the plurality of second bonding pads BP2 disposed between two second semiconductor chips 200 adjacent to each other in the vertical direction (the Z direction) among the plurality of second semiconductor chips 200. For example, the second front insulation layer 290 may surround upper portions of the plurality of first bonding pads BP1 or upper portions of the plurality of second bonding pads BP2.

The second backside insulation layer 270 may surround partial portions of the plurality of second bonding pads BP2 disposed between two second semiconductor chips 200 adjacent to each other in the vertical direction (the Z direction) among the plurality of second semiconductor chips 200. For example, the second backside insulation layer 270 may surround lower portions of the plurality of second bonding pads BP2.

An upper surface of the first backside insulation layer 170 of the first semiconductor chip 100 may contact a lower surface of the second front insulation layer 290 of the lowermost second semiconductor chip 200 of the plurality of second semiconductor chips 200. The first backside insulation layer 170 of the first semiconductor chip 100 and the second front insulation layer 290 of the lowermost second semiconductor chip 200 of the plurality of second semiconductor chips 200 may surround the plurality of first bonding pads BP1. For example, the plurality of first bonding pads BP1 may pass through the first backside insulation layer 170 of the first semiconductor chip 100 and the second front insulation layer 290 of the lowermost second semiconductor chip 200 of the plurality of second semiconductor chips 200.

An upper surface of a second backside insulation layer 270 of a lower second semiconductor chip 200 of two second semiconductor chips 200 adjacent to each other in the vertical direction (the Z direction) among the plurality of second semiconductor chips 200 may contact a lower surface of a second front insulation layer 290 of an upper second semiconductor chip 200 of the two second semiconductor chips 200. The second backside insulation layer 270 of the lower second semiconductor chip 200 and the second front insulation layer 290 of the upper second semiconductor chip 200 may surround the plurality of second bonding pads BP2. For example, the plurality of second bonding pads BP2 disposed between the two second semiconductor chips 200 adjacent to each other in the vertical direction (the Z direction) may pass through the second backside insulation layer 270 of the lower second semiconductor chip 200 and the second front insulation layer 290 of the upper second semiconductor chip 200.

The uppermost second semiconductor chip 200T, which is a second semiconductor chip 200 disposed farthest away from the first semiconductor chip 100 and disposed at an uppermost portion of the semiconductor package 1 among the plurality of second semiconductor chips 200, may not include the plurality of second through-electrodes 230 and the second backside insulation layer 270. In some implementations, the uppermost second semiconductor chip 200T may include a first bonding insulation layer 272 covering the second inactive surface 202B of the second semiconductor substrate 202 included in the uppermost second semiconductor chip 200T. The first bonding insulation layer 272 may be referred to as a second backside insulation layer. For example, each of the plurality of second semiconductor chips 200 may include the second backside insulation layer, and the uppermost second semiconductor chip 200T may not include the plurality of second through-electrodes 230.

In some implementations, a vertical height of each of the plurality of second semiconductor chips 200 may have substantially the same value. In some implementations, a vertical height of each of the other second semiconductor chips 200, except the uppermost second semiconductor chip 200T, of the plurality of second semiconductor chips 200 may have substantially the same value, and a vertical height of the uppermost second semiconductor chip 200T may have a value which is greater than that of each of the other second semiconductor chips 200.

The plurality of first bonding pads BP1 may electrically connect the plurality of first through-electrodes 130, included in the first semiconductor chip 100, to the plurality of second through-electrodes 230 included in the lowermost second semiconductor chip 200 of the plurality of second semiconductor chips 200. The plurality of second bonding pads BP2 may electrically connect, with each other, the plurality of second through-electrodes 230 included in each of the two second semiconductor chips 200 adjacent to each other in the vertical direction (the Z direction) among the plurality of second semiconductor chips 200. For example, a plurality of bonding pads including the plurality of first bonding pads BP1 and the plurality of second bonding pads BP2 may electrically connect the plurality of first through-electrodes 130, included in the first semiconductor chip 100, to the plurality of second through-electrodes 230 included in the plurality of second semiconductor chips 200. In some implementations, each of the plurality of first bonding pads BP1 and the plurality of second bonding pads BP2 may include a material including copper (Cu).

The plurality of first bonding pads BP1 may be surrounded by the first backside insulation layer 170 and the second front insulation layer 290, and the plurality of second bonding pads BP2 may be surrounded by the second backside insulation layer 270 and the second front insulation layer 290. The plurality of first bonding pads BP1 may pass through the first backside insulation layer 170 and the second front insulation layer 290, and the plurality of second bonding pads BP2 may pass through the second backside insulation layer 270 and the second front insulation layer 290.

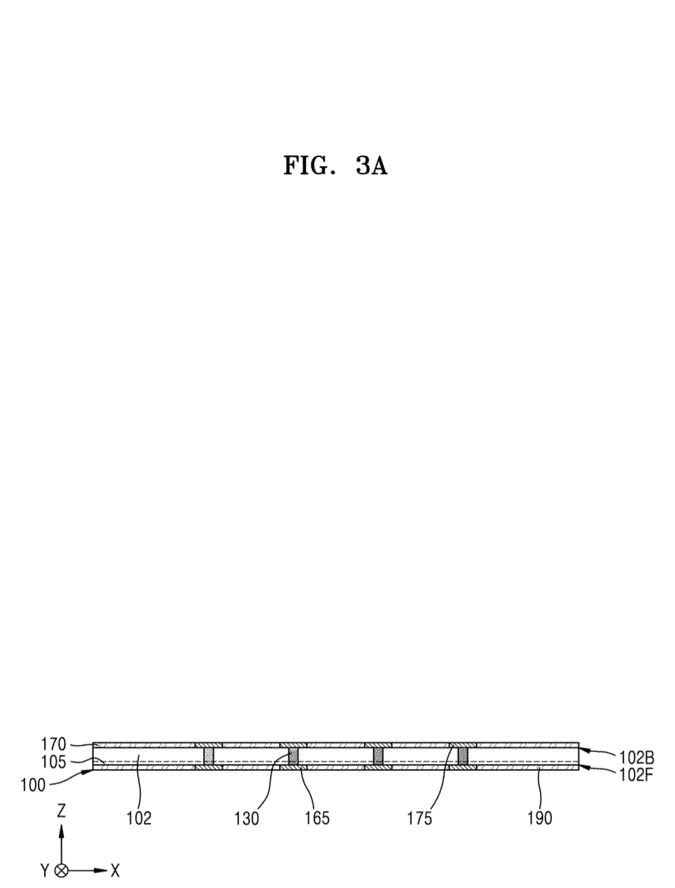

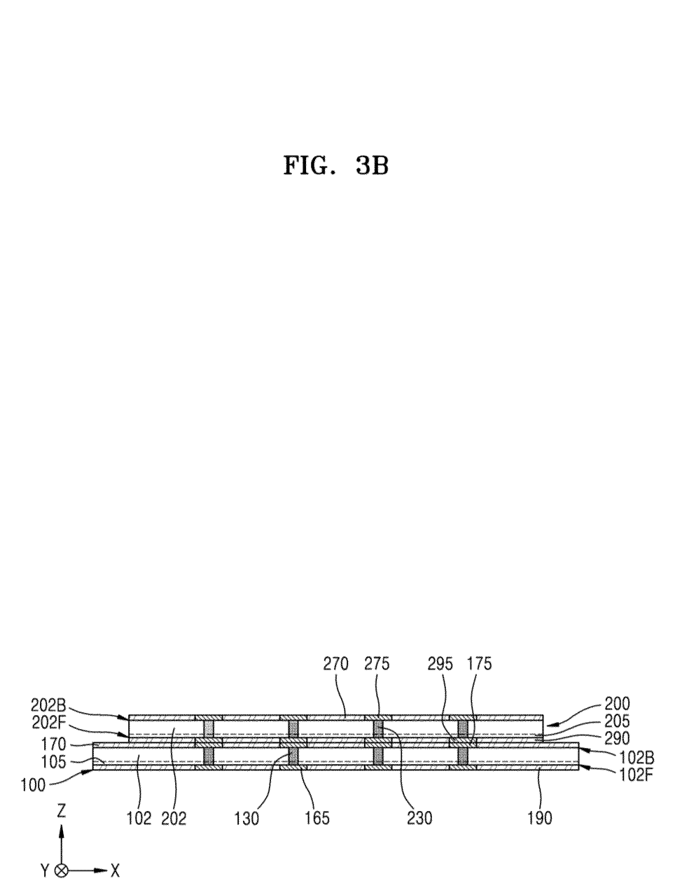

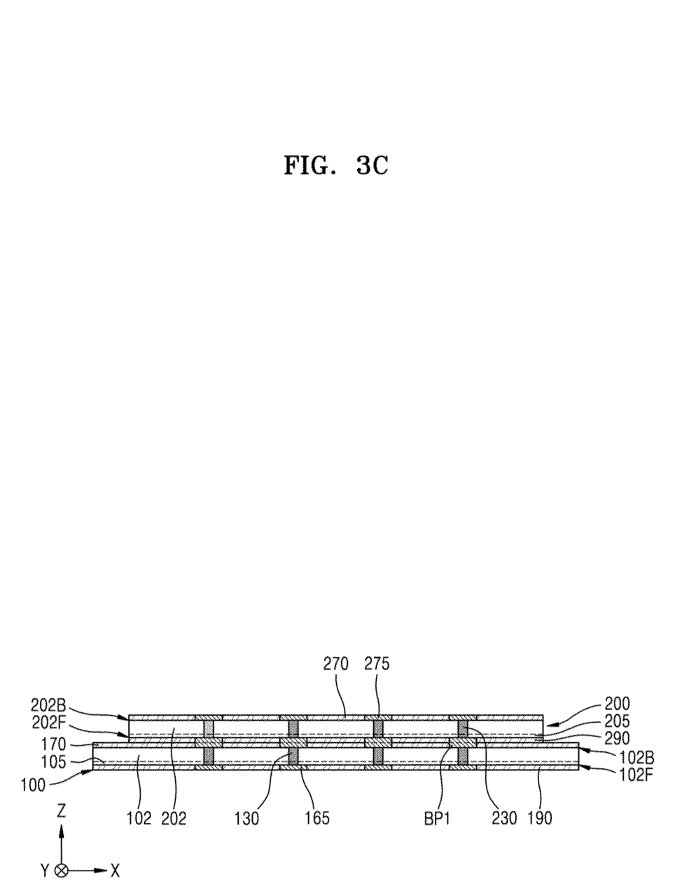

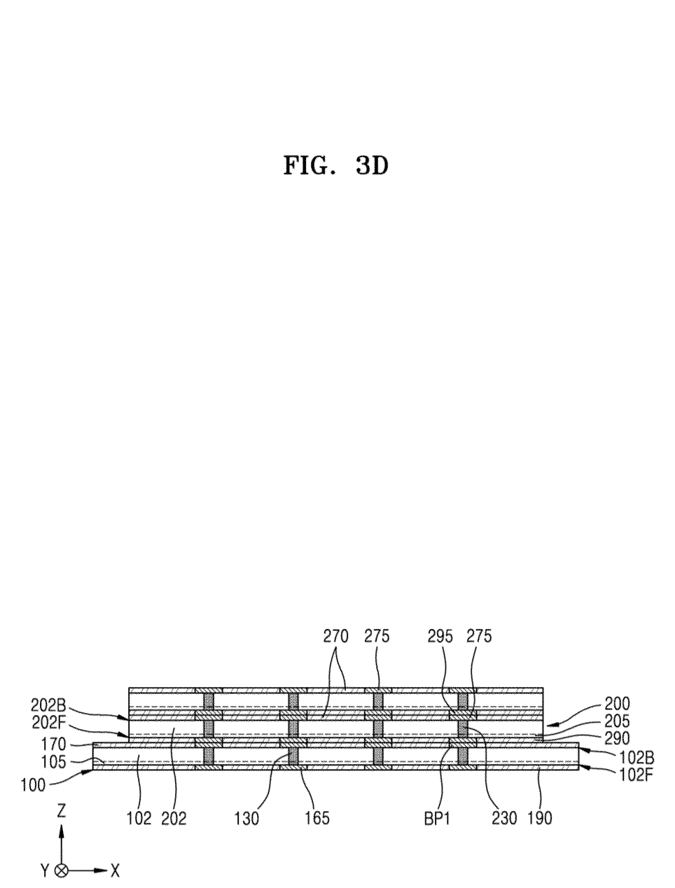

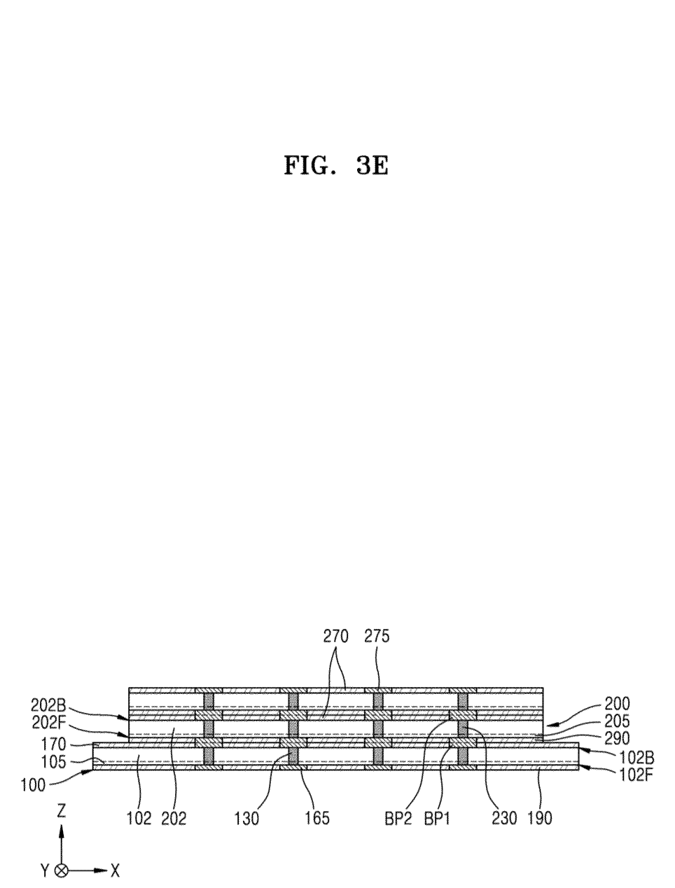

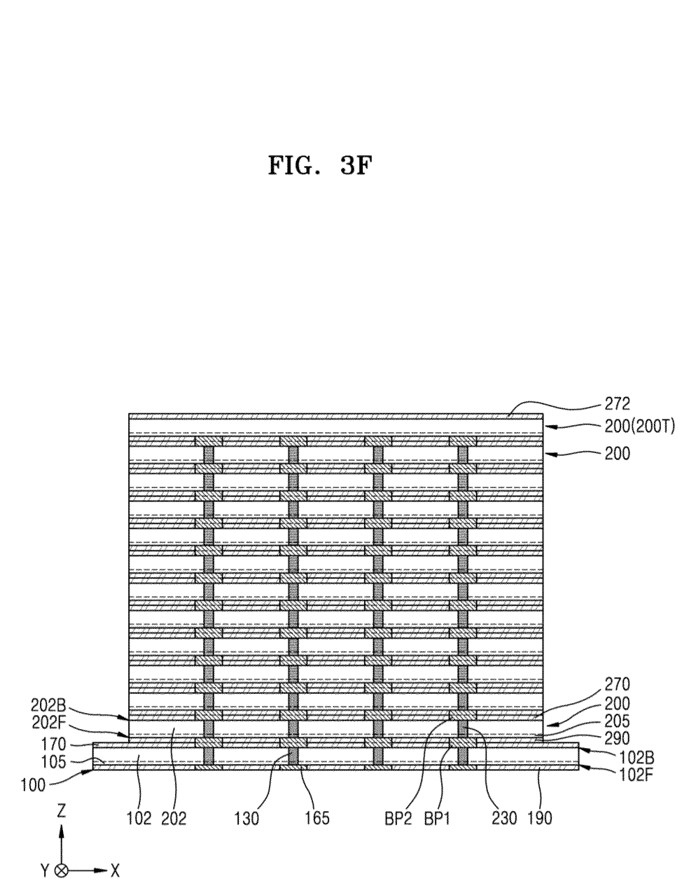

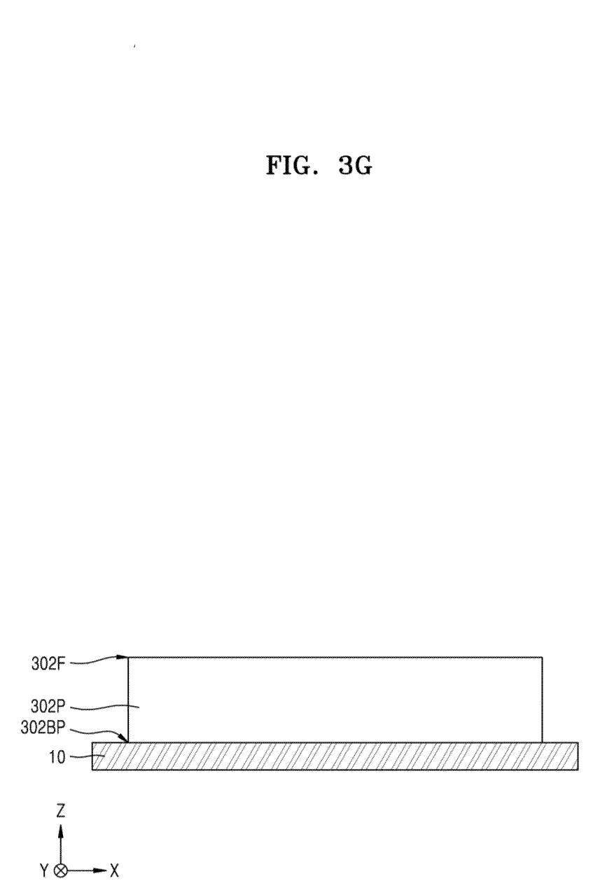

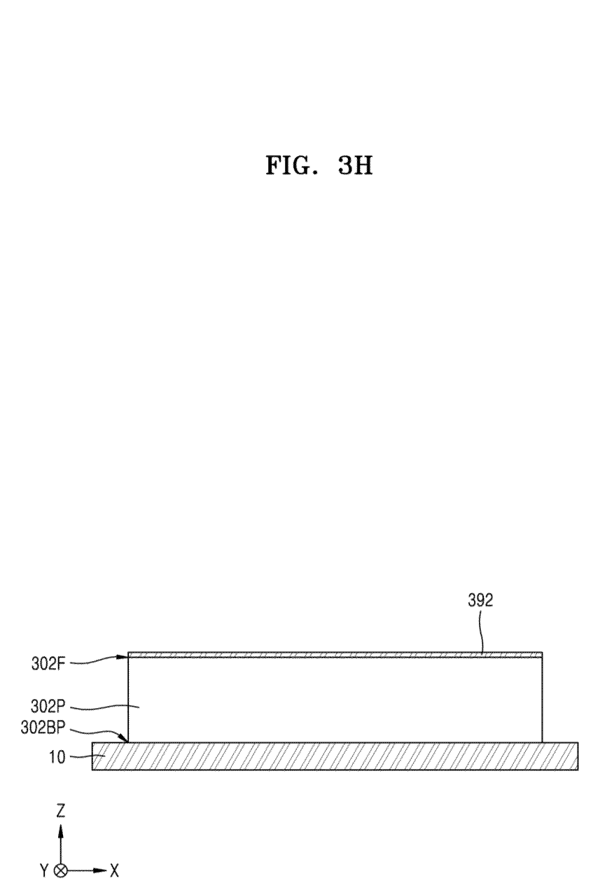

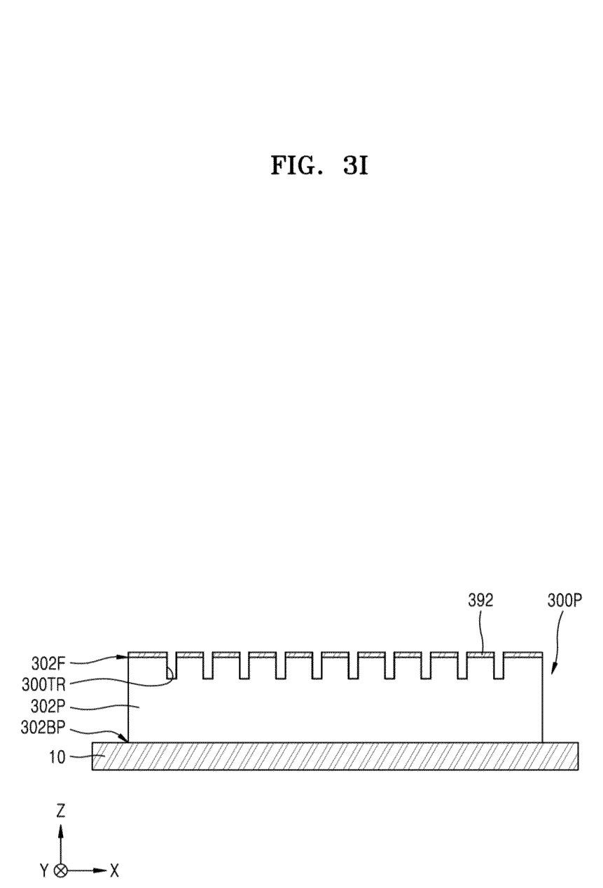

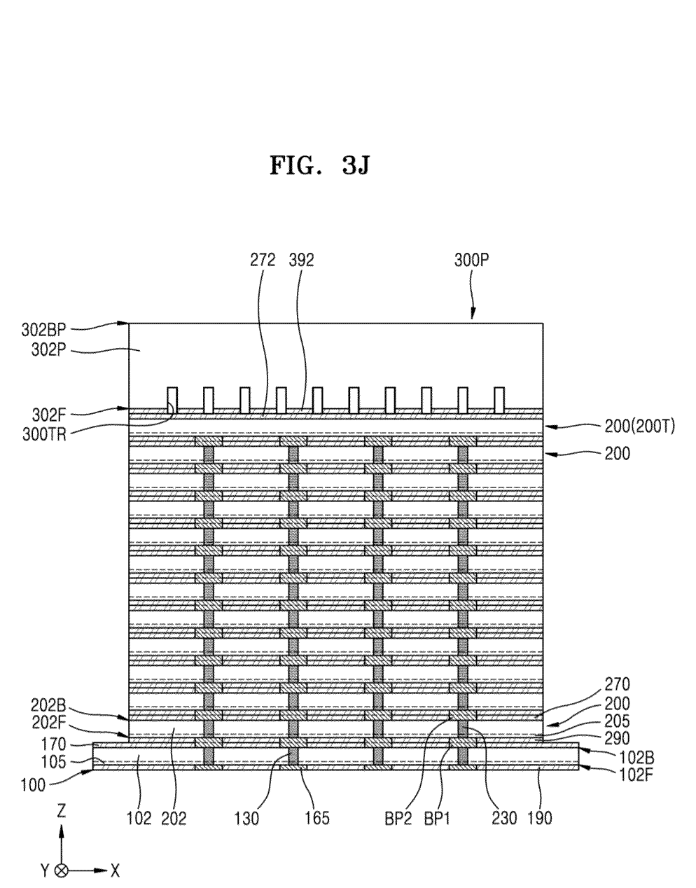

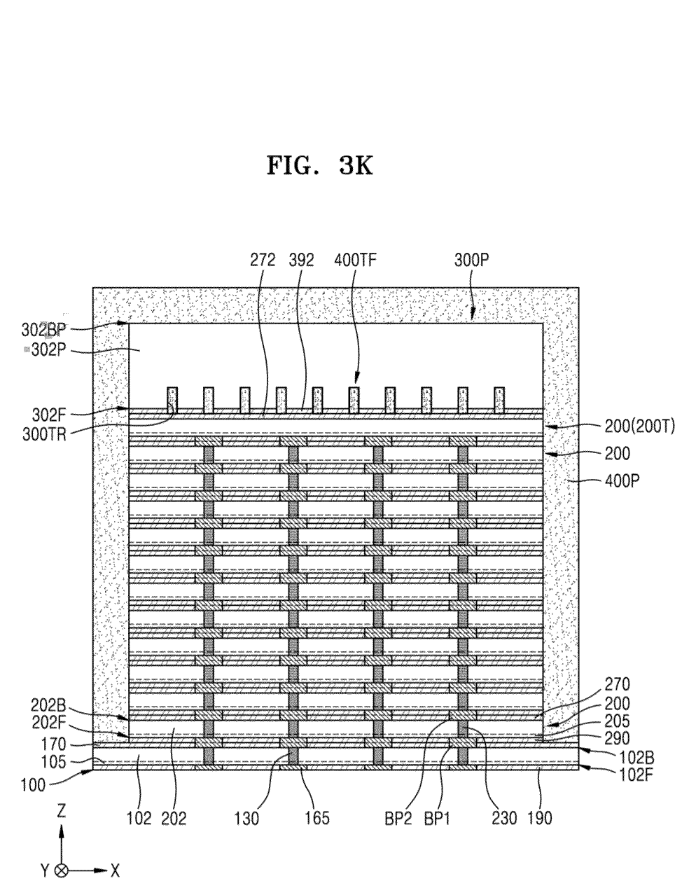

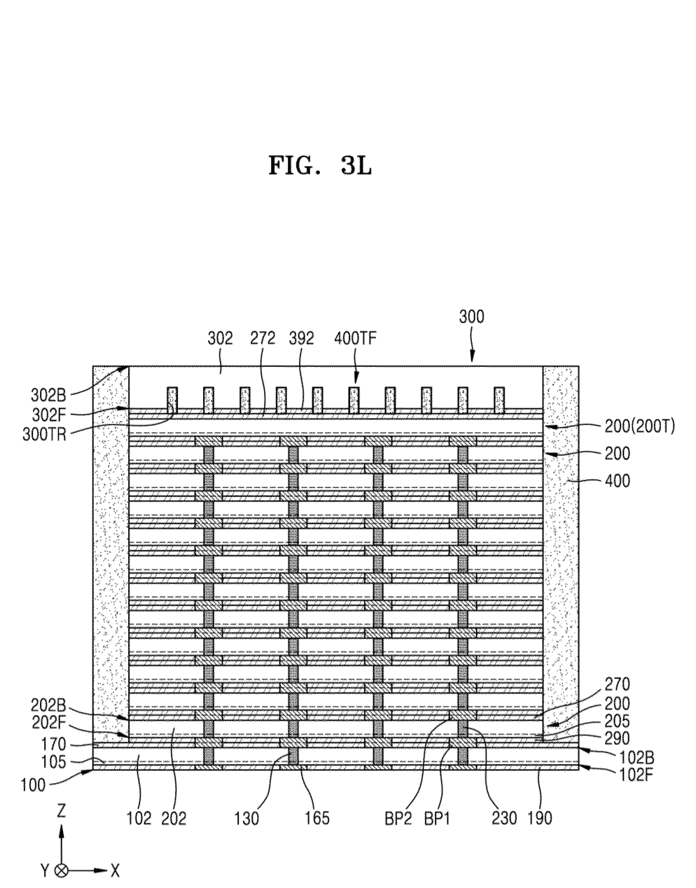

Lower portions of the plurality of first bonding pads BP1 surrounded by the first backside insulation layer 170 may be portions corresponding to a plurality of first backside chip connection pads 175 illustrated in FIG. 3A, upper portions of the plurality of first bonding pads BP1 and upper portions of the plurality of second bonding pads BP2 each surrounded by the second front insulation layer 290 may be portions corresponding to a plurality of second front chip connection pads 295 illustrated in FIGS. 3B and 3D, and lower portions of the plurality of second bonding pads BP2 surrounded by the second backside insulation layer 270 may be portions corresponding to a plurality of second backside chip connection pads 275 illustrated in FIGS. 3B to 3E. For example, the plurality of first bonding pads BP1 may be formed through diffusion bonding so that the plurality of first backside chip connection pads 175 included in the first semiconductor chip 100 and the plurality of second front chip connection pads 295 included in the lowermost second semiconductor chip 200 of the plurality of second semiconductor chips 200 expand with heat to contact each other and are provided as one body through diffusion of metal elements included in the plurality of first backside chip connection pads 175 and the plurality of second front chip connection pads 295. For example, the plurality of second bonding pads BP2 may be formed through diffusion bonding so that a plurality of second backside chip connection pads 275 and the plurality of second front chip connection pads 295, which are included in two second semiconductor chips 200 adjacent to each other in the vertical direction (the Z direction) and are opposite to each other, expand with heat to contact each other and are provided as one body through diffusion of metal elements included in the plurality of second backside chip connection pads 275 and the plurality of second front chip connection pads 295.

Each of the first backside insulation layer 170, the second front insulation layer 290, and the second backside insulation layer 270 may include one material of silicon oxide (SiO), silicon nitride (SiN), silicon carbonitride (SiCN), silicon carbide oxide (SiCO), and a polymer material. The polymer material may be benzocyclobutene (BCB), polyimide (PI), polybenzoxazole (PBO), silicone, acrylate, or epoxy. In some implementations, each of the first backside insulation layer 170, the second front insulation layer 290, and the second backside insulation layer 270 may include the same material. In some implementations, the first backside insulation layer 170 and the second front insulation layer 290 may include different materials, and the second backside insulation layer 270 and the second front insulation layer 290 may include different materials. The second backside insulation layer 270 and the first bonding insulation layer 272 may include the same material, but are not limited thereto. The first front insulation layer 190 and the second front insulation layer 290 may include the same material, but are not limited thereto. For example, the first front insulation layer 190 may include SiO, and the second front insulation layer 290 may include one material of SiN, SiCN, SiCO, and a polymer material.

The first backside insulation layer 170 and the plurality of first bonding pads BP1 may cover all of the first inactive surface 102B of the first semiconductor substrate 102, and the second backside insulation layer 270 and the plurality of second bonding pads BP2 may cover all of the second inactive surface 202B of the second semiconductor substrate 202. That is, the first backside insulation layer 170 may cover a portion of the first inactive surface 102B of the first semiconductor substrate 102 and may not cover the other portion thereof, and the second backside insulation layer 270 may cover a portion of the second inactive surface 202B of the second semiconductor substrate 202 and may not cover the other portion thereof. The first bonding insulation layer 272 may cover all of the second inactive surface 202B of the second semiconductor substrate 202 included in the uppermost second semiconductor chip 200T.

The first backside insulation layer 170 and the second front insulation layer 290 which are opposite to each other and surround the plurality of first bonding pads BP1 and the second backside insulation layer 270 and the second front insulation layer 290 which are opposite to each other and surround the plurality of second bonding pads BP2 may configure a covalent bond and may be bonded to each other. That is, the first semiconductor chip 100 and the plurality of second semiconductor chips 200 may be stacked by hybrid bonding.

In the semiconductor package 1, the first semiconductor chip 100 may be disposed so that the first active surface 102F of the first semiconductor substrate 102 faces a lower side and the first inactive surface 102B faces an upper side, and the second semiconductor chip 200 may be disposed so that the second active surface 202F of the second semiconductor substrate 202 faces a lower side and the second inactive surface 202B faces an upper side. Each of the plurality of second semiconductor chips 200 may be sequentially stacked on the first semiconductor chip 100 so that the second active surface 202F faces the first inactive surface 102B of the first semiconductor chip 100.

Unless separately described herein, an upper surface of the first semiconductor chip 100 included in the semiconductor package 1 may represent a side which faces the first inactive surface 102B of the first semiconductor substrate 102, a lower surface of the first semiconductor chip 100 may represent a side which faces the first active surface 102F of the first semiconductor substrate 102, an upper surface of the second semiconductor chip 200 may represent a side which faces the second inactive surface 202B of the second semiconductor substrate 202, and a lower surface of the second semiconductor chip 200 may represent a side which faces the second active surface 202F of the second semiconductor substrate 202. The lower surface of the first semiconductor chip 100 facing the first active surface 102F of the first semiconductor substrate 102 may be referred to as a front surface of the first semiconductor chip 100, and the upper surface of the first semiconductor chip 100 facing the first inactive surface 102B may be referred to as a backside surface of the first semiconductor chip 100. The lower surface of the second semiconductor chip 200 facing the second active surface 202F of the second semiconductor substrate 202 may be referred to as a front surface of the second semiconductor chip 200, and the upper surface of the second semiconductor chip 200 facing the second inactive surface 202B may be referred to as a backside surface of the second semiconductor chip 200.

A horizontal width and a horizontal area of the first semiconductor chip 100 may respectively have values which are greater than those of a horizontal width and a horizontal area of each of the plurality of second semiconductor chips 200. The upper surface and the lower surface (i.e., the backside surface and the front surface) of the first semiconductor chip 100 may have substantially the same horizontal width and horizontal area. The upper surface and the lower surface (i.e., the backside surface and the front surface) of each of the plurality of second semiconductor chips 200 may have substantially the same horizontal width and horizontal area.

The first semiconductor substrate 102 and the second semiconductor substrate 202 may include, for example, a semiconductor material, such as silicon (Si). In some implementations, the first semiconductor substrate 102 and the second semiconductor substrate 202 may include a semiconductor material, such as germanium (Ge). Each of the first semiconductor substrate 102 and the second semiconductor substrate 202 may include a conductive region (for example, an impurity-doped well) adjacent to each of the first active surface 102F and the second active surface 202F. Each of the first semiconductor substrate 102 and the second semiconductor substrate 202 may have various device isolation structures such as a shallow trench isolation (STI) structure adjacent to each of the first active surface 102F and the second active surface 202F.

Each of the first semiconductor device 105 and the second semiconductor device 205 may include various kinds of a plurality of individual devices. The plurality of individual devices may include various microelectronic devices, and for example, may include metal-oxide-semiconductor field effect transistors (MOSFETs) such as complementary metal-oxide-semiconductor (CMOS) transistors, system large scale integration (LSI), image sensors such as CMOS imaging sensors (CISs), micro-electro-mechanical system (MEMS), active devices, and passive devices. The plurality of individual devices may be electrically connected to the conductive region of the first semiconductor substrate 102 or the second semiconductor substrate 202. Each of the first semiconductor device 105 and the second semiconductor device 205 may further include a conductive plug or a conductive wiring which electrically connects at least two of the plurality of individual devices or the plurality of individual devices to the conductive region of each of the first semiconductor substrate 102 and the second semiconductor substrate 202. Also, each of the plurality of individual devices may be electrically isolated from other individual devices adjacent thereto by an insulation layer.

At least one of the first semiconductor chip 100 and the second semiconductor chip 200 may be a memory semiconductor chip. In some implementations, the first semiconductor chip 100 may be a buffer chip which includes a serial-parallel conversion circuit and is for controlling the plurality of second semiconductor chips 200, and each of the plurality of second semiconductor chips 200 may be a memory chip including memory cells. For example, the semiconductor package 1 including the first semiconductor chip 100 and the plurality of second semiconductor chips 200 may be a high bandwidth memory (HBM), the first semiconductor chip 100 may be referred to as an HBM controller die, and each of the plurality of second semiconductor chips 200 may be referred to as a dynamic random access memory (DRAM) die.

Each of the first through-electrode 130 and the second through-electrode 230 may include a through silicon via (TSV). Each of the first through-electrode 130 and the second through-electrode 230 may include a conductive plug passing through each of the first semiconductor substrate 102 and the second semiconductor substrate 202 and a conductive barrier layer surrounding the conductive plug. The conductive plug may have a circular pillar shape, and the conductive barrier layer may have a cylindrical shape which surrounds a sidewall of the conductive plug. A via insulation layer may be disposed between the first through-electrode 130 and the first semiconductor substrate 102 and between the second through-electrode 230 and the second semiconductor substrate 202 and may surround sidewalls of the first through-electrode 130 and the second through-electrode 230. Each of the first through-electrode 130 and the second through-electrode 230 may be formed in one of a via-first structure, a via-middle structure, and a via-last structure.

The dummy chip 300 may include a dummy substrate 302 which includes a substrate bottom (or a substrate bottom surface) 302F and a substrate top (or a substrate top surface) 302B opposite to each other and a second bonding insulation layer 392 which covers the substrate bottom 302F of the dummy substrate 302. The dummy chip 300 may include a plurality of trenches 300TR which pass through the second bonding insulation layer 392 from a lower surface of the dummy chip 300 (i.e., a lower surface of the second bonding insulation layer 392) and extend into the dummy substrate 302 from the substrate bottom 302F of the dummy substrate 302. The second bonding insulation layer 392 may be divided into a plurality of layers which are apart from one another in a horizontal direction by the plurality of trenches 300TR. In some implementations, a vertical height (i.e., a thickness) of the dummy chip 300 may have a value which is greater than that of a vertical height (i.e., a thickness) of each of the first semiconductor chip 100 and the plurality of second semiconductor chips 200.

The dummy substrate 302 may include, for example, a semiconductor material, such as Si. In some implementations, the dummy substrate 302 may include only a semiconductor material. For example, the dummy substrate 302 may be a portion of the bare wafer. The second bonding insulation layer 392 may include one material of SiO, SiN, SiCN, SiCO, and a polymer material. The second bonding insulation layer 392 and the first bonding insulation layer 272 may include the same material, but are not limited thereto. For example, the second bonding insulation layer 392 may include a material which differs from that of the first bonding insulation layer 272. In some implementations, the second bonding insulation layer 392 may include the same material as that of the second front insulation layer 290.

In some implementations, the plurality of trenches 300TR may connect with each other in the dummy chip 300. In some implementations, the plurality of trenches 300TR may not connect with each other and may be apart from each other, in the dummy chip 300. The plurality of trenches 300TR may pass through the second bonding insulation layer 392 from a lower surface of the second bonding insulation layer 392 and may extend into the dummy substrate 302, but may not extend to the substrate top 302B of the dummy substrate 302. For example, only the dummy substrate 302 may be exposed at an upper surface of the dummy chip 300. Each of the plurality of trenches 300TR may one-dimensionally extend toward an inner portion of the dummy chip 300 from a side surface of the dummy chip 300 in a horizontal direction. The one-dimensional arrangement of the plurality of trenches 300TR will be described below in detail with reference to FIGS. 2A to 2D.

The semiconductor package 1 may further include a package molding layer 400 which surrounds the plurality of second semiconductor chips 200 and the dummy chip 300, on the first semiconductor chip 100. The package molding layer 400 may include, for example, an epoxy mold compound (EMC). The package molding layer 400 may cover a portion of an upper surface of the first semiconductor chip 100 which is not covered by the second semiconductor chip 200, side surfaces of the plurality of second semiconductor chips 200, and a side surface of the dummy chip 300 and may fill the plurality of trenches 300TR. Therefore, the plurality of trenches 300TR may receive a filling molding portion 400TF. A portion, filling the plurality of trenches 300TR, of the package molding layer 400 may be referred to as a filling molding portion 400TF. The filling molding portion 400TF of the package molding layer 400 may be disposed between a divided plurality of second bonding insulation layers 392. The package molding layer 400 may not cover the upper surface of the dummy chip 300, namely, the substrate top 302B of the dummy substrate 302. For example, the upper surface of the dummy chip 300 and an upper surface of the package molding layer 400 may configure a coplanar surface. In some embodiments, a heat dissipation member may be attached to the upper surface of the dummy chip 300 with a thermal interface material (TIM) therebetween.

A portion of an upper surface of the first bonding insulation layer 272 may contact a lower surface of the second bonding insulation layer 392, and the other portion of the upper surface of the first bonding insulation layer 272 may contact a lower surface of the filling molding portion 400TF of the package molding layer 400. For example, the upper surface of the first bonding insulation layer 272 may all be covered by the second bonding insulation layer 392 and the filling molding portion 400TF of the package molding layer 400.

In the semiconductor package 1, the dummy chip 300 may include the plurality of trenches 300TR filled by the filling molding portion 400TF of the package molding layer 400, at a side facing the uppermost second semiconductor chip 200T. The plurality of second semiconductor chips 200 may be stacked on the first semiconductor chip 100, and thus, even when warpage occurs in an upper surface of the uppermost second semiconductor chip 200T, the occurrence of a void between the uppermost second semiconductor chip 200T and the dummy chip 300 may be prevented, thereby enhancing the structural reliability of the semiconductor package 1. Also, in the uppermost second semiconductor chip 200T and the dummy chip 300, the first bonding insulation layer 272 and the second bonding insulation layer 392 of the dummy chip 300 may configure a covalent bond and may be bonded to each other, and thus, heat occurring in the semiconductor package 1 may be efficiently dissipated to the outside.

In FIGS. 1 and 2A, the semiconductor package 1 may include a dummy chip 300. The dummy chip 300 may include a plurality of trenches 300TR which pass through a substrate bottom 302F of a dummy substrate 302 from a lower surface of the dummy chip 300 and extend into the dummy substrate 302. Each of the plurality of trenches 300TR may one-dimensionally extend in a horizontal direction between side surfaces, which are opposite to each other, of the dummy chip 300. Some of the plurality of trenches 300TR may extend in a first horizontal direction (an X direction) and may extend from one side surface of the dummy chip 300 to the other side surface, which is opposite to the one side surface, of the dummy chip 300 in the first horizontal direction (the X direction), and the other of the plurality of trenches 300TR may extend in a second horizontal direction (a Y direction) and may extend from one side surface of the dummy chip 300 to the other side surface, which is opposite to the one side surface, of the dummy chip 300 in the second horizontal direction (the Y direction). The first horizontal direction (the X direction) may be perpendicular to the second horizontal direction (the Y direction). The plurality of trenches 300TR may connect with each other. For example, some of the plurality of trenches 300TR extending in the first horizontal direction (the X direction) and the other of the plurality of trenches 300TR extending in the second horizontal direction (the Y direction) may connect with each other.

The plurality of trenches 300TR may be connected to at least one side surface of the dummy chip 300 and may connect with each other, and, in a case where a mold material is implanted into the first semiconductor chip 100 on which the plurality of second semiconductor chips 200 and the dummy chip 300 are stacked, so as to form the package molding layer 400, the mold material may be implanted into the plurality of trenches 300TR and may form the filling molding portion 400TF of the package molding layer 400 filling the plurality of trenches 300TR.

Each of the plurality of trenches 300TR may have a trench horizontal width WT and may extend in a horizontal direction. Two trenches 300TR adjacent to each other among the plurality of trenches 300TR may have a trench interval IV and may be apart from each other. Each of the plurality of trenches 300TR may have a trench depth DT in a vertical direction (a Z direction). For example, the trench horizontal width WT may be about 1 μm to about 5 μm. For example, the trench interval IV may be about 5 μm to about 50 μm. For example, the trench depth DT may be about 1 μm to about 100 μm. The trench interval IV may be greater than the trench horizontal width WT. The trench depth DT may be greater than the trench horizontal width WT and the trench interval IV. The trench depth DT may be less than a vertical height (i.e., a thickness) of the dummy chip 300.

In FIGS. 1 and 2B, the semiconductor package 1 may include a dummy chip 300. The dummy chip 300 may include a plurality of trenches 300TR which pass through a substrate bottom 302F of a dummy substrate 302 from a lower surface of the dummy chip 300 and extend into the dummy substrate 302. Each of the plurality of trenches 300TR may one-dimensionally extend between side surfaces, which are opposite to each other, of the dummy chip 300. The plurality of trenches 300TR may extend in a first horizontal direction (an X direction) and may extend from one side surface of the dummy chip 300 to the other side surface, which is opposite to the one side surface, of the dummy chip 300 in the first horizontal direction (the X direction). The plurality of trenches 300TR may not connect with each other and may be apart from each other, in the dummy chip 300.

Each of the plurality of trenches 300TR may extend from the one side surface of the dummy chip 300 to the other side surface, which is opposite to the one side surface, of the dummy chip 300 in the first horizontal direction (the X direction), and, in a case where a mold material is implanted into the first semiconductor chip 100 on which the plurality of second semiconductor chips 200 and the dummy chip 300 are stacked, so as to form the package molding layer 400, the mold material may be implanted into the plurality of trenches 300TR and may form the filling molding portion 400TF of the package molding layer 400 filling the plurality of trenches 300TR.

In FIGS. 1 and 2C, the semiconductor package 1 may include a dummy chip 300. The dummy chip 300 may include a plurality of trenches 300TR which pass through a substrate bottom 302F of a dummy substrate from a lower surface of the dummy chip 300 and extend into the dummy substrate 302. Each of the plurality of trenches 300TR may one-dimensionally extend between side surfaces, which are opposite to each other, of the dummy chip 300. The plurality of trenches 300TR may extend in a second horizontal direction (a Y direction) and may extend from one side surface of the dummy chip 300 to the other side surface, which is opposite to the one side surface, of the dummy chip 300 in the second horizontal direction (the Y direction). The plurality of trenches 300TR may not connect with each other and may be apart from each other, in the dummy chip 300.

Each of the plurality of trenches 300TR may extend from the one side surface of the dummy chip 300 to the other side surface, which is opposite to the one side surface, of the dummy chip 300 in the second horizontal direction (the Y direction), and, in a case where a mold material is implanted into the first semiconductor chip 100 on which the plurality of second semiconductor chips 200 and the dummy chip 300 are stacked, so as to form the package molding layer 400, the mold material may be implanted into the plurality of trenches 300TR and may form the filling molding portion 400TF of the package molding layer 400 filling the plurality of trenches 300TR.

In FIGS. 1 and 2D, the semiconductor package 1 may include a dummy chip 300. The dummy chip 300 may include a plurality of trenches 300TR which pass through a substrate bottom 302F of a dummy substrate from a lower surface of the dummy chip 300 and extend into the dummy substrate 302. Each of the plurality of trenches 300TR may one-dimensionally extend into the dummy chip 300 from one side surface of the dummy chip 300 in a horizontal direction. Some of the plurality of trenches 300TR may extend in a first horizontal direction (an X direction) and may extend from one side surface of the dummy chip 300 to the other side surface, which is opposite to the one side surface, of the dummy chip 300 in the first horizontal direction (the X direction), the other some of the plurality of trenches 300TR may extend in a second horizontal direction (a Y direction) and may extend from one side surface of the dummy chip 300 to the other side surface, which is opposite to the one side surface, of the dummy chip 300 in the second horizontal direction (the Y direction), and the other some of the plurality of trenches 300TR may extend in a horizontal direction from one side surface of the dummy chip 300 to connect with at least one of the some trenches 300TR and the other some trenches 300TR among the plurality of trenches 300TR.

The plurality of trenches 300TR may be connected to at least one side surface of the dummy chip 300 and may connect with each other, and, in a case where a mold material is implanted into the first semiconductor chip 100 on which the plurality of second semiconductor chips 200 and the dummy chip 300 are stacked, so as to form the package molding layer 400, the mold material may be implanted into the plurality of trenches 300TR and may form the filling molding portion 400TF of the package molding layer 400 filling the plurality of trenches 300TR.

FIGS. 3A to 3L are cross-sectional views illustrating stage-by-stage an example of a method of manufacturing a semiconductor package according to some implementations. In FIG. 3A, a first semiconductor chip 100, which includes a first semiconductor substrate 102 including a first active surface 102F and a first inactive surface 102B opposite to each other, a first semiconductor device 105 disposed on the first active surface 102F of the first semiconductor substrate 102, a plurality of first through-electrodes 130 passing through at least a portion of the first semiconductor substrate 102, a plurality of first front chip connection pads 165 electrically connected to the plurality of first through-electrodes 130 on the first active surface 102F of the first semiconductor substrate 102, a plurality of first backside chip connection pads 175 electrically connected to the plurality of first through-electrodes 130 on the first inactive surface 102B of the first semiconductor substrate 102, a first front insulation layer 190 surrounding the plurality of first front chip connection pads 165 on the first active surface 102F of the first semiconductor substrate 102, and a first backside insulation layer 170 surrounding the plurality of first backside chip connection pads 175 on the first inactive surface 102B of the first semiconductor substrate 102, may be prepared.

In FIG. 3B, a second semiconductor chip 200, which includes a second semiconductor substrate 202 including a second active surface 202F and a second inactive surface 202B opposite to each other, a second semiconductor device 205 disposed on the second active surface 202F of the second semiconductor substrate 202, a plurality of second through-electrodes 230 passing through at least a portion of the second semiconductor substrate 202, a plurality of second front chip connection pads 295 electrically connected to the plurality of second through-electrodes 230 on the second active surface 202F of the second semiconductor substrate 202, a plurality of second backside chip connection pads 275 electrically connected to the plurality of second through-electrodes 230 on the second inactive surface 202B of the second semiconductor substrate 202, a second front insulation layer 290 surrounding the plurality of second front chip connection pads 295 on the second active surface 202F of the second semiconductor substrate 202, and a second backside insulation layer 270 surrounding the plurality of second backside chip connection pads 275 on the second inactive surface 202B of the second semiconductor substrate 202, may be prepared.

The second semiconductor chip 200 may be disposed on the first semiconductor chip 100 so that the second front insulation layer 290 of the second semiconductor chip 200 faces the first backside insulation layer 170 of the first semiconductor chip 100. The plurality of second front chip connection pads 295 and the plurality of first backside chip connection pads 175, corresponding to each other, may overlap each other in a vertical direction (a Z direction).

In FIGS. 3B and 3C, by applying heat and/or pressure in a process of placing the second semiconductor chip 200 on the first semiconductor chip 100, the first backside insulation layer 170 of the first semiconductor chip 100 may be bonded to the second front insulation layer 290 of the second semiconductor chip 200. The first backside insulation layer 170 of the first semiconductor chip 100 and the second front insulation layer 290 of the second semiconductor chip 200 may configure a covalent bond and may be bonded to each other. For example, heat of a first temperature may be applied in the process of placing the second semiconductor chip 200 on the first semiconductor chip 100.

Subsequently, by applying heat of a second temperature which is higher than the first temperature, the plurality of first backside chip connection pads 175 of the first semiconductor chip 100 and the plurality of second front chip connection pads 295 of the second semiconductor chip 200 corresponding to each other may be bonded to each other to form a plurality of first bonding pads BP1. The first backside chip connection pads 175 may correspond to a lower portion of the first bonding pad BP1, and the second front chip connection pad 295 may correspond to an upper portion of the first bonding pad BP1. The plurality of first bonding pads BP1 may be formed through diffusion bonding so that the plurality of first backside chip connection pads 175 and the plurality of second front chip connection pads 295 corresponding to each other expand with heat to contact each other, and then, are provided as one body through diffusion of metal elements included in the plurality of first backside chip connection pads 175 and the plurality of second front chip connection pads 295 corresponding to each other. That is, the second semiconductor chip 200 may be attached to the first semiconductor chip 100 by hybrid bonding.

In FIG. 3D, another second semiconductor chip 200 may be disposed on the second semiconductor chip 200 attached to the first semiconductor chip 100. The other second semiconductor chip 200 may be disposed on the second semiconductor chip 200 attached to the first semiconductor chip 100 so that a second front insulation layer 290 of the other semiconductor chip 200 (i.e., an upper second semiconductor chip 200) faces a second backside insulation layer 270 of the second semiconductor chip 200 (i.e., a lower second semiconductor chip 200) attached to the first semiconductor chip 100. A plurality of second front chip connection pads 295 included in the upper second semiconductor chip 200 and a plurality of second backside chip connection pads 275 included in the lower second semiconductor chip 200, corresponding to each other, may overlap each other in a vertical direction (a Z direction).

In FIGS. 3D and 3E, by applying heat and/or pressure in a process of placing the upper second semiconductor chip 200 on the lower second semiconductor chip 200, the second backside insulation layer 270 of the lower second semiconductor chip 200 may be bonded to the second front insulation layer 290 of the upper second semiconductor chip 200. The second backside insulation layer 270 of the lower second semiconductor chip 200 and the second front insulation layer 290 of the upper second semiconductor chip 200 may configure a covalent bond and may be bonded to each other. For example, heat of the first temperature may be applied in the process of placing the upper second semiconductor chip 200 on the lower second semiconductor chip 200.

Subsequently, by applying heat of the second temperature which is higher than the first temperature, the plurality of second backside chip connection pads 275 of the lower second semiconductor chip 200 and the plurality of second front chip connection pads 295 of the upper second semiconductor chip 200 corresponding to each other may be bonded to each other to form a plurality of second bonding pads BP2. The second backside chip connection pad 275 of the lower second semiconductor chip 200 may correspond to a lower portion of the second bonding pad BP2, and the second front chip connection pad 295 of the upper second semiconductor chip 200 may correspond to an upper portion of the second bonding pad BP2. The plurality of second bonding pads BP2 may be formed through diffusion bonding so that the plurality of second backside chip connection pads 275 and the plurality of second front chip connection pads 295 corresponding to each other expand with heat to contact each other, and then, are provided as one body through diffusion of metal elements included in the plurality of second backside chip connection pads 275 and the plurality of second front chip connection pads 295 corresponding to each other. That is, the upper second semiconductor chip 200 may be attached to the lower second semiconductor chip 200 by hybrid bonding.

In FIG. 3F, a plurality of second semiconductor chips 200 may be sequentially attached to a first semiconductor chip 100 with reference to FIGS. 3D and 3F. An uppermost second semiconductor chip 200T, which is a second semiconductor chip 200 disposed farthest away from the first semiconductor chip 100 and disposed at an uppermost portion of the semiconductor package 1 among the plurality of second semiconductor chips 200, may not include the plurality of second through-electrodes 230 and the second backside insulation layer 270. In some implementations, the uppermost second semiconductor chip 200T may include a first bonding insulation layer 272 covering the second inactive surface 202B of the second semiconductor substrate 202 included in the uppermost second semiconductor chip 200T.

In FIG. 3G, a preliminary dummy substrate 302P including a first surface 302BP and a second surface 302F opposite to each other may be attached to a supporting film 10. The preliminary dummy substrate 302P may be attached to the supporting film 10 so that the first surface 302BP faces the supporting film 10. In some implementations, the supporting film 10 may be a dicing tape.

In FIG. 3H, a second bonding insulation layer 392 covering the second surface 302F of the preliminary dummy substrate 302P may be formed.

In FIG. 3I, a plurality of trenches 300TR which pass through the second bonding insulation layer 392 from an upper surface of the second bonding insulation layer 392 and extend into the preliminary dummy substrate 302P from the second surface 302F of the preliminary dummy substrate 302P may be formed, and a preliminary dummy chip 300P, which includes the preliminary dummy substrate 302P and the second bonding insulation layer 392 covering the second surface 302F of the preliminary dummy substrate 302P and includes the plurality of trenches 300TR passing through the second bonding insulation layer 392 from the upper surface of the second bonding insulation layer 392 and extending into the preliminary dummy substrate 302P, may be formed.

In FIGS. 3I and 3J, the preliminary dummy chip 300P may be isolated from the supporting film 10, and the preliminary dummy chip 300P may be disposed on an uppermost second semiconductor chip 200T. The preliminary dummy chip 300P may be disposed on the uppermost second semiconductor chip 200T so that the second bonding insulation layer 392 faces a first bonding insulation layer 272 of the uppermost second semiconductor chip 200T. The first surface 302BP of the preliminary dummy substrate 302P may face an upper side, and the second surface 302F of the preliminary dummy substrate 302P may face the uppermost second semiconductor chip 200T. By applying heat and/or pressure in a process of placing the preliminary dummy chip 300P on the uppermost second semiconductor chip 200T, the first bonding insulation layer 272 of the uppermost second semiconductor chip 200T may be bonded to the second bonding insulation layer 392 of the dummy chip 300P. The first bonding insulation layer 272 of the uppermost second semiconductor chip 200T and the second bonding insulation layer 392 of the dummy chip 300P may configure a covalent bond and may be bonded to each other. For example, heat of the first temperature may be applied in the process of placing the preliminary dummy chip 300P on the uppermost second semiconductor chip 200T.

In FIG. 3K, a preliminary molding layer 400P surrounding the plurality of second semiconductor chips 200 and the preliminary dummy chip 300P may be formed on the first semiconductor chip 100. The preliminary molding layer 400P may cover a portion of an upper surface of the first semiconductor chip 100 which is not covered by the second semiconductor chip 200, side surfaces of the plurality of second semiconductor chips 200, a side surface of the preliminary dummy chip 300P, and the first surface 302BP of the preliminary dummy substrate 302P of the preliminary dummy chip 300P and may fill the plurality of trenches 300TR. A portion, filling the plurality of trenches 300TR, of the preliminary molding layer 400P may be referred to as a filling molding portion 400TF.

In FIGS. 3K and 3L, the dummy chip 300 including the dummy substrate 302 and the package molding layer 400 may be formed by removing a partial upper portion of the preliminary dummy substrate 302P of the preliminary dummy chip 300P and a partial upper portion of the preliminary molding layer 400P. In a process of forming the dummy chip 300 including the dummy substrate 302 and the package molding layer 400, a partial upper portion of the preliminary dummy substrate 302P and a partial upper portion of the preliminary molding layer 400P may be removed so that the filling molding portion 400TF of the package molding layer 400 is not removed. The dummy substrate 302 included in the dummy chip 300 may include a substrate top 302B and a substrate bottom 302F opposite to each other. The second surface 302F of the preliminary dummy substrate 302P may be the substrate bottom 302F of the dummy substrate 302, and a surface exposed by a partial upper portion thereof from the first surface 302BP of the preliminary dummy substrate 302P may be the substrate top 302B of the dummy substrate 302. For example, an upper surface of the dummy chip 300 (i.e., the substrate top 302B of the dummy substrate 302) and an upper surface of the package molding layer 400 may configure a coplanar surface.

Subsequently, the plurality of package connection terminals 500 illustrated in FIG. 1 may be attached to the plurality of first front chip connection pads 165, and the semiconductor package 1 may be formed.

In FIGS. 1 and 3A to 3L, the dummy chip 300 including the plurality of trenches 300TR may be attached to an upper surface of the uppermost second semiconductor chip 200T, and the plurality of trenches 300TR may be filled by the filling molding portion 400TF of the package molding layer 400. Accordingly, the plurality of second semiconductor chips 200 may be attached to the first semiconductor chip 100, and even when warpage occurs in the upper surface of the uppermost second semiconductor chip 200T, a void between the uppermost second semiconductor chip 200T and the dummy chip 300 may be prevented from occurring by the plurality of trenches 300TR and the filling molding portion 400TF, thereby enhancing the structural reliability of the semiconductor package 1. Also, the first bonding insulation layer 272 of the uppermost second semiconductor chip 200T and the second bonding insulation layer 392 of the dummy chip 300 may configure a covalent bond and may be bonded to each other, and thus, the dummy chip 300 may be attached to the uppermost second semiconductor chip 200T, whereby heat occurring in the semiconductor package 1 may be efficiently dissipated to the outside.

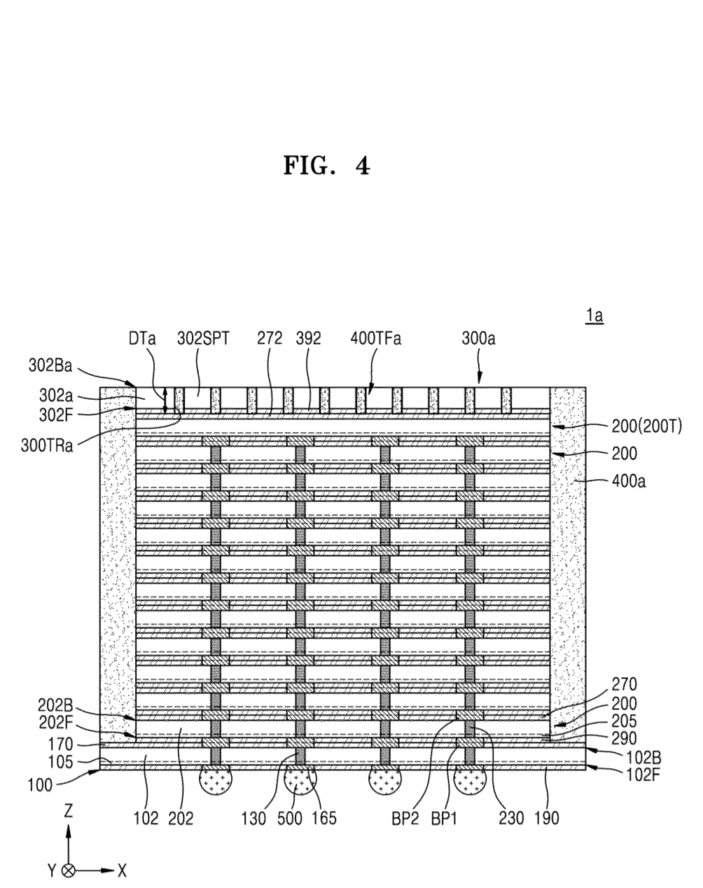

FIG. 4 is a cross-sectional view illustrating an example of a semiconductor package according to some implementations. In FIG. 4, a semiconductor package 1a may include a first semiconductor chip 100, a plurality of second semiconductor chips 200 stacked on the first semiconductor chip 100, a dummy chip 300a attached to an uppermost second semiconductor chip 200T, and a package molding layer 400a surrounding the plurality of second semiconductor chips 200 and the dummy chip 300a on the first semiconductor chip 100. In some implementations, a vertical height (i.e., a thickness) of the dummy chip 300a may have a value which is greater than that of a vertical height (i.e., a thickness) of each of the first semiconductor chip 100 and the plurality of second semiconductor chips 200.

The dummy chip 300 may include a dummy substrate 302a which includes a substrate bottom 302F and a substrate top 302Ba opposite to each other and a second bonding insulation layer 392 which covers the substrate bottom 302F of the dummy substrate 302a. The dummy chip 300a may include a plurality of trenches 300TRa passing through the second bonding insulation layer 392 and the dummy substrate 302a. For example, the plurality of trenches 300TRa may extend to an upper surface of the dummy chip 300a (i.e., the substrate top 302Ba of the dummy substrate 302a) from a lower surface of the dummy chip 300a (i.e., a lower surface of the second bonding insulation layer 392) and may pass through the dummy chip 300a. Each of the plurality of trenches 300TRa may have a trench depth DTa in a vertical direction (a Z direction). For example, the trench depth DTa may be about 30 μm to about 100 μm. The trench depth DTa may be equal to a vertical height (i.e., a thickness) of the dummy chip 300a. The package molding layer 400a may include, for example, an EMC. The package molding layer 400a may cover a portion of an upper surface of the first semiconductor chip 100 which is not covered by the second semiconductor chip 200, side surfaces of the plurality of second semiconductor chips 200, and a side surface of the dummy chip 300a and may fill the plurality of trenches 300TRa. A portion, filling the plurality of trenches 300TRa, of the package molding layer 400a may be referred to as a filling molding portion 400TFa. The package molding layer 400a may not cover the upper surface of the dummy chip 300a, namely, the substrate top 302Ba of the dummy substrate 302a. For example, the upper surface of the dummy chip 300a and an upper surface of the package molding layer 400a may configure a coplanar surface.

The dummy substrate 302a may include, for example, a semiconductor material, such as Si. In some implementations, the plurality of trenches 300TRa may connect with each other in the dummy chip 300a. In some implementations, the plurality of trenches 300TRa may not connect with each other and may be apart from each other, in the dummy chip 300a. For example, the substrate top 302Ba of the dummy substrate 302 and the filling molding portion 400TFa of the package molding layer 400a may be exposed at the upper surface of the dummy chip 300a. The one-dimensional arrangement of the plurality of trenches 300TRa may be substantially the same as the one-dimensional arrangement of the plurality of trenches 300TR illustrated in FIGS. 2A and 2B. The dummy substrate 302a may be configured with a plurality of substrate isolators 302SPT which are apart from one another in a horizontal direction by the plurality of trenches 300TRa. A filling molding portion 400TFa of the package molding layer 400a may be disposed between the plurality of substrate isolators 302SPT.

In a process of removing a partial upper portion of the preliminary molding layer 400P and a partial upper portion of the preliminary dummy substrate 302P illustrated in FIG. 3K, a dummy chip 300a including the dummy substrate 302a and the package molding layer 400a may be formed by removing the partial upper portion of the preliminary molding layer 400P and the partial upper portion of the preliminary dummy substrate 302P so that the filling molding portion 400TFa of the package molding layer 400a is exposed.

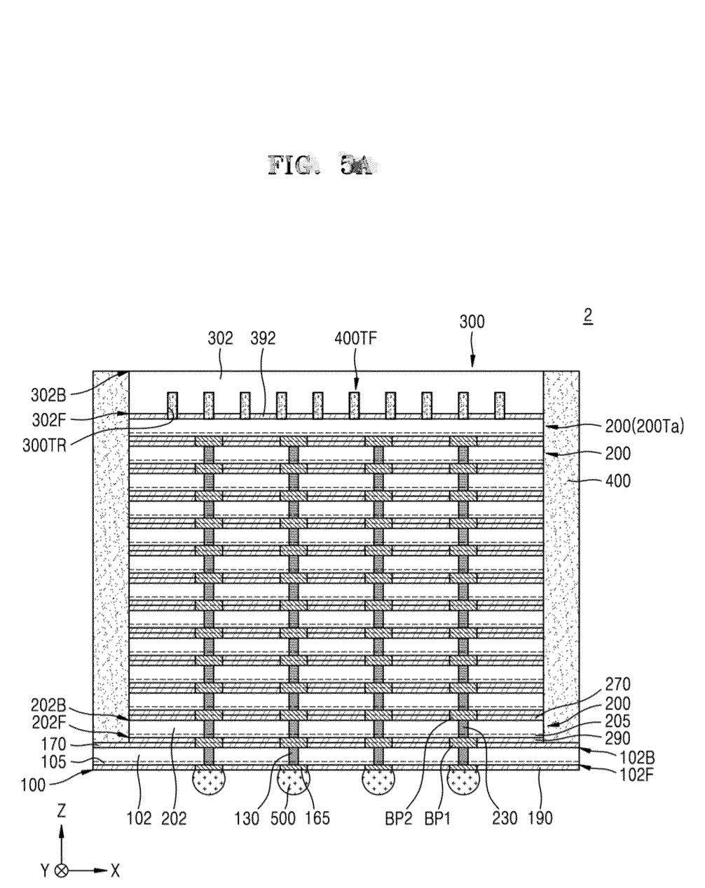

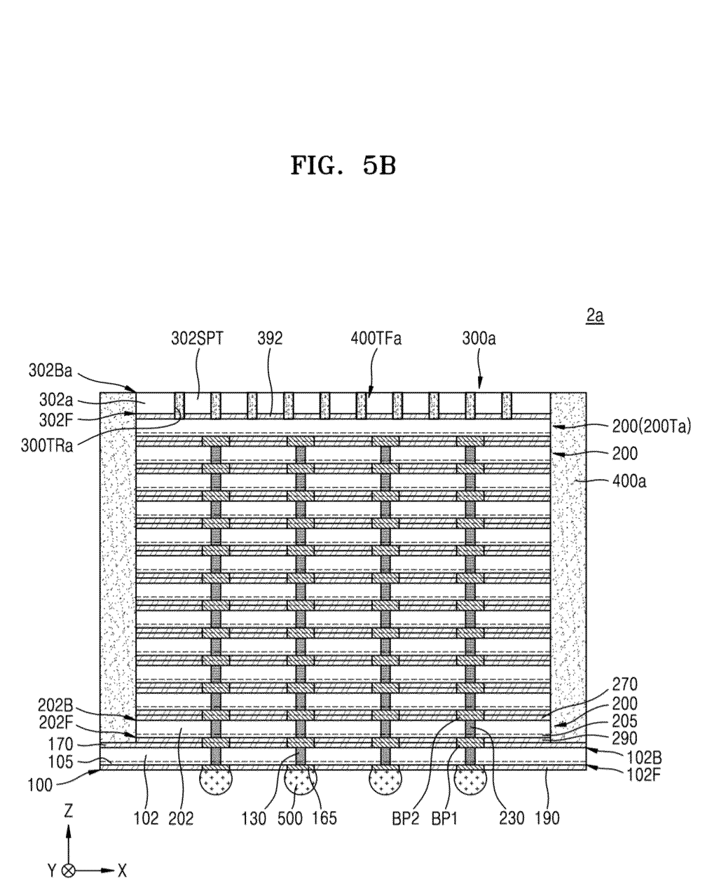

FIGS. 5A and 5B are cross-sectional views illustrating an example of a semiconductor package according to some implementations. In FIG. 5A, a semiconductor package 2 may include a first semiconductor chip 100, a plurality of second semiconductor chips 200 stacked on the first semiconductor chip 100, a dummy chip 300 attached to an uppermost second semiconductor chip 200Ta, and a package molding layer 400 surrounding the plurality of second semiconductor chips 200 and the dummy chip 300 on the first semiconductor chip 100.

An uppermost second semiconductor chip 200 of the plurality of second semiconductor chips 200 may be referred to as an uppermost second semiconductor chip 200Ta. The uppermost second semiconductor chip 200Ta, which is a second semiconductor chip 200 disposed farthest away from the first semiconductor chip 100 and disposed at an uppermost portion of the semiconductor package 2 among the plurality of second semiconductor chips 200, may not include the plurality of second through-electrodes 230 and the second backside insulation layer 270.

A second inactive surface 202B of a second semiconductor substrate 202 of the uppermost second semiconductor chip 200Ta may contact a lower surface of a second bonding insulation layer 392 of the dummy chip 300 and a lower surface of a filling molding portion 400TF of the package molding layer 400. For example, the second inactive surface 202B of the second semiconductor substrate 202 of the uppermost second semiconductor chip 200Ta may all be covered by the lower surface of the second bonding insulation layer 392 of the dummy chip 300 and the lower surface of the filling molding portion 400TF of the package molding layer 400. The second bonding insulation layer 392 of the dummy chip 300 and the second semiconductor substrate 202 of the uppermost second semiconductor chip 200Ta may configure a covalent bond and may be bonded to each other. The second bonding insulation layer 392 of the dummy chip 300 may be referred to as a bonding insulation layer.

In the semiconductor package 2, the dummy chip 300 may include a plurality of trenches 300TR filled by the filling molding portion 400TF of the package molding layer 400, at a side facing the uppermost second semiconductor chip 200Ta. The plurality of second semiconductor chips 200 may be stacked on the first semiconductor chip 100, and even when warpage occurs in an upper surface of the uppermost second semiconductor chip 200Ta, the occurrence of a void between the uppermost second semiconductor chip 200Ta and the dummy chip 300 may be prevented, thereby enhancing the structural reliability of the semiconductor package 2. Also, in the uppermost second semiconductor chip 200Ta and the dummy chip 300, the second semiconductor substrate 202 and the second bonding insulation layer 392 may configure a covalent bond and may be bonded to each other, and heat occurring in the semiconductor package 2 may be efficiently dissipated to the outside.

In FIG. 5B, a semiconductor package 2a may include a first semiconductor chip 100, a plurality of second semiconductor chips 200 stacked on the first semiconductor chip 100, a dummy chip 300a attached to an uppermost second semiconductor chip 200Ta, and a package molding layer 400a surrounding the plurality of second semiconductor chips 200 and the dummy chip 300a on the first semiconductor chip 100. The uppermost second semiconductor chip 200Ta, which is a second semiconductor chip 200 disposed farthest away from the first semiconductor chip 100 and disposed at an uppermost portion of the semiconductor package 2a among the plurality of second semiconductor chips 200, may not include the plurality of second through-electrodes 230 and the second backside insulation layer 270. A portion, filling the plurality of trenches 300TRa, of the package molding layer 400a may be referred to as a filling molding portion 400TFa.

A second inactive surface 202B of a second semiconductor substrate 202 of the uppermost second semiconductor chip 200Ta may contact a lower surface of a second bonding insulation layer 392 of the dummy chip 300a and a lower surface of a filling molding portion 400TFa of the package molding layer 400a. For example, the second inactive surface 202B of the second semiconductor substrate 202 may all be covered by the lower surface of the second bonding insulation layer 392 of the dummy chip 300a and the lower surface of the filling molding portion 400TFa of the package molding layer 400a. The second bonding insulation layer 392 of the dummy chip 300a and the second inactive surface 202B of the second semiconductor substrate 202 may configure a covalent bond and may be bonded to each other.

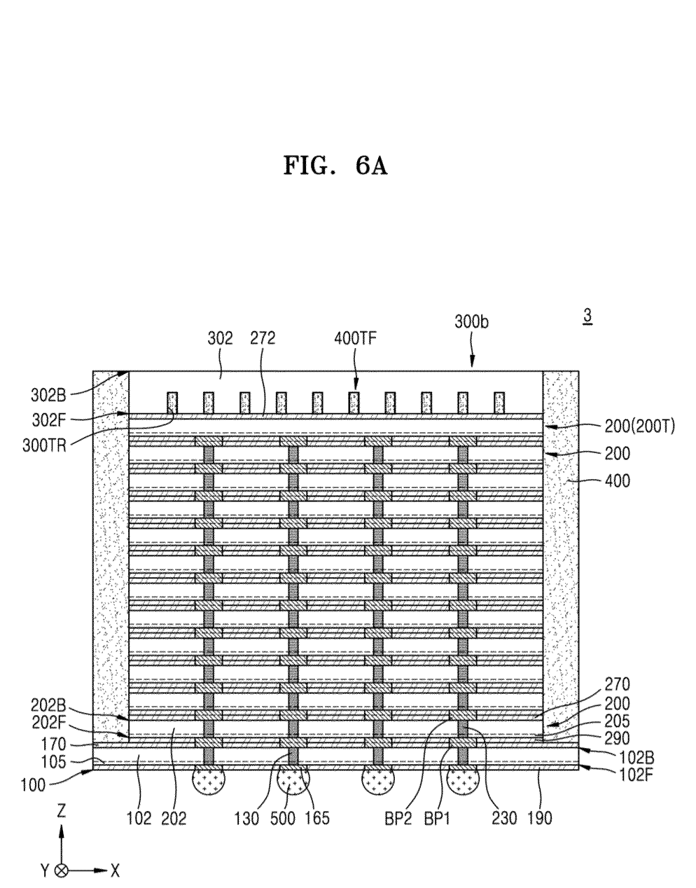

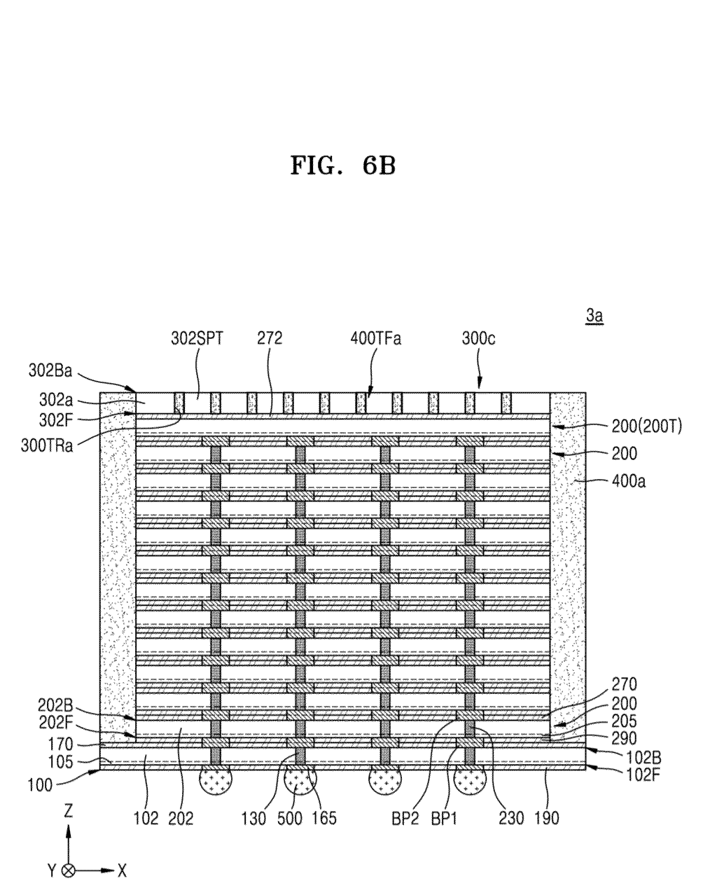

FIGS. 6A and 6B are cross-sectional views illustrating an example of a semiconductor package according to some implementations. In FIG. 6A, a semiconductor package 3 may include a first semiconductor chip 100, a plurality of second semiconductor chips 200 stacked on the first semiconductor chip 100, a dummy chip 300b attached to an uppermost second semiconductor chip 200T, and a package molding layer 400 surrounding the plurality of second semiconductor chips 200 and the dummy chip 300b on the first semiconductor chip 100. The dummy chip 300b may include a dummy substrate 302 which includes a substrate bottom 302F and a substrate top 302B opposite to each other and may include a plurality of trenches 300TR which extend into the dummy substrate 302 from a substrate bottom 302F of the dummy substrate 302. The dummy chip 300b may not include a second bonding insulation layer 392 included in the dummy chip 300 illustrated in FIG. 1. The package molding layer 400 may cover a portion of an upper surface of the first semiconductor chip 100 which is not covered by the second semiconductor chip 200, side surfaces of the plurality of second semiconductor chips 200, and a side surface of the dummy chip 300b and may fill the plurality of trenches 300TR. A portion, filling the plurality of trenches 300TR, of the package molding layer 400 may be referred to as a filling molding portion 400TF.

An upper surface of a first bonding insulation layer 272 of an uppermost second semiconductor chip 200T may contact the substrate bottom 302F of the dummy substrate 302 of the dummy chip 300b and the lower surface of the filling molding portion 400TF of the package molding layer 400. For example, the upper surface of the first bonding insulation layer 272 of the uppermost second semiconductor chip 200T may all be covered by the substrate bottom 302F of the dummy substrate 302 of the dummy chip 300b and the lower surface of the filling molding portion 400TF of the package molding layer 400. The dummy substrate 302 and the first bonding insulation layer 272 of the uppermost second semiconductor chip 200T may configure a covalent bond and may be bonded to each other. The first bonding insulation layer 272 of the uppermost second semiconductor chip 200T may be referred to as a bonding insulation layer.

In the semiconductor package 3, the dummy chip 300b may include the plurality of trenches 300TR filled by the filling molding portion 400TF of the package molding layer 400, at a side facing the uppermost second semiconductor chip 200T. The plurality of second semiconductor chips 200 may be stacked on the first semiconductor chip 100, and even when warpage occurs in an upper surface of the uppermost second semiconductor chip 200T, the occurrence of a void between the uppermost second semiconductor chip 200T and the dummy chip 300b may be prevented, thereby enhancing the structural reliability of the semiconductor package 3. Also, in the uppermost second semiconductor chip 200T and the dummy chip 300b, the first bonding insulation layer 272 and the dummy substrate 302 may configure a covalent bond and may be bonded to each other, and thus, heat occurring in the semiconductor package 3 may be efficiently dissipated to the outside.

In FIG. 6B, a semiconductor package 3a may include a first semiconductor chip 100, a plurality of second semiconductor chips 200 stacked on the first semiconductor chip 100, a dummy chip 300c attached to an uppermost second semiconductor chip 200T, and a package molding layer 400a surrounding the plurality of second semiconductor chips 200 and the dummy chip 300c on the first semiconductor chip 100.

The dummy chip 300c may include a dummy substrate 302a which includes a substrate bottom 302F and a substrate top 302Ba opposite to each other and may include a plurality of trenches 300TRa passing through the dummy substrate 302a. The dummy chip 300c may not include a second bonding insulation layer 392 included in the dummy chip 300a illustrated in FIG. 4. The package molding layer 400a may cover a portion of an upper surface of the first semiconductor chip 100 which is not covered by the second semiconductor chip 200, side surfaces of the plurality of second semiconductor chips 200, and a side surface of the dummy chip 300c and may fill the plurality of trenches 300TRa. A portion, filling the plurality of trenches 300TRa, of the package molding layer 400a may be referred to as a filling molding portion 400TFa.

An upper surface of a first bonding insulation layer 272 of an uppermost second semiconductor chip 200T may contact the substrate bottom 302F of the dummy substrate 302a of the dummy chip 300c and the lower surface of the filling molding portion 400TFa of the package molding layer 400a. For example, the upper surface of the first bonding insulation layer 272 of the uppermost second semiconductor chip 200T may all be covered by the substrate bottom 302F of the dummy substrate 302a of the dummy chip 300c and the lower surface of the filling molding portion 400TFa of the package molding layer 400a. The dummy substrate 302a and the first bonding insulation layer 272 of the uppermost second semiconductor chip 200T may configure a covalent bond and may be bonded to each other. The first bonding insulation layer 272 of the uppermost second semiconductor chip 200T may be referred to as a bonding insulation layer.

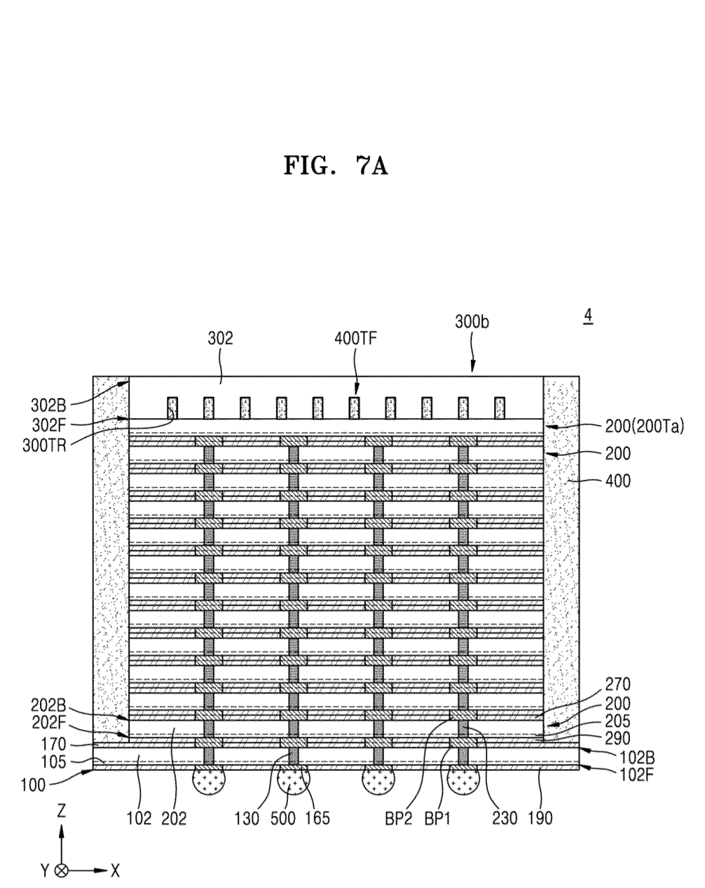

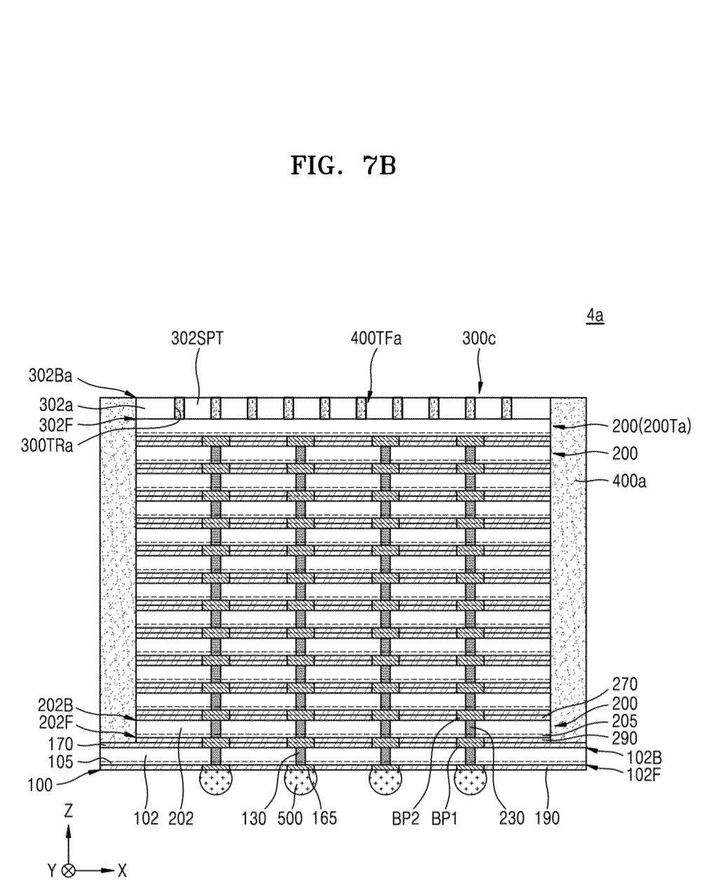

FIGS. 7A and 7B are cross-sectional views illustrating an example of a semiconductor package according to some implementations. In FIG. 7A, a semiconductor package 4 may include a first semiconductor chip 100, a plurality of second semiconductor chips 200 stacked on the first semiconductor chip 100, a dummy chip 300b attached to an uppermost second semiconductor chip 200Ta, and a package molding layer 400 surrounding the plurality of second semiconductor chips 200 and the dummy chip 300b on the first semiconductor chip 100.

The uppermost second semiconductor chip 200T, which is a second semiconductor chip 200 disposed farthest away from the first semiconductor chip 100 and disposed at an uppermost portion of the semiconductor package 4 among the plurality of second semiconductor chips 200, may not include the plurality of second through-electrodes 230 and the second backside insulation layer 270. The dummy chip 300b may include a dummy substrate 302 which includes a substrate bottom 302F and a substrate top 302B opposite to each other and may include a plurality of trenches 300TR which extend into the dummy substrate 302 from a substrate bottom 302F of the dummy substrate 302. The dummy chip 300b may not include a second bonding insulation layer 392 included in the dummy chip 300 illustrated in FIG. 1.

The package molding layer 400 may cover a portion of an upper surface of the first semiconductor chip 100 which is not covered by the second semiconductor chip 200, side surfaces of the plurality of second semiconductor chips 200, and a side surface of the dummy chip 300b and may fill the plurality of trenches 300TR. A portion, filling the plurality of trenches 300TR, of the package molding layer 400 may be referred to as a filling molding portion 400TF.

A second inactive surface 202B of a second semiconductor substrate 202 of the uppermost second semiconductor chip 200Ta may contact a substrate bottom 302F of a dummy substrate 302 of the dummy chip 300b and a lower surface of a filling molding portion 400TF of the package molding layer 400. For example, a second inactive surface 202B of a second semiconductor substrate 202 of the uppermost second semiconductor chip 200Ta may all be covered by the substrate bottom 302F of the dummy substrate 302 of the dummy chip 300b and the lower surface of the filling molding portion 400TF of the package molding layer 400. The dummy substrate 302 of the dummy chip 300b and the second semiconductor substrate 202 of the uppermost second semiconductor chip 200Ta may configure a covalent bond and may be bonded to each other.

In the semiconductor package 4, the dummy chip 300b may include the plurality of trenches 300TR filled by the filling molding portion 400TF of the package molding layer 400, at a side facing the uppermost second semiconductor chip 200Ta. The plurality of second semiconductor chips 200 may be stacked on the first semiconductor chip 100, and even when warpage occurs in an upper surface of the uppermost second semiconductor chip 200Ta, the occurrence of a void between the uppermost second semiconductor chip 200Ta and the dummy chip 300b may be prevented, thereby enhancing the structural reliability of the semiconductor package 4. Also, in the uppermost second semiconductor chip 200Ta and the dummy chip 300b, the second semiconductor substrate 202 and the dummy substrate 302 may configure a covalent bond and may be bonded to each other, and thus, heat occurring in the semiconductor package 4 may be efficiently dissipated to the outside.

In FIG. 7B, a semiconductor package 4a may include a first semiconductor chip 100, a plurality of second semiconductor chips 200 stacked on the first semiconductor chip 100, a dummy chip 300c attached to an uppermost second semiconductor chip 200Ta, and a package molding layer 400a surrounding the plurality of second semiconductor chips 200 and the dummy chip 300c on the first semiconductor chip 100.

The dummy chip 300c may include a dummy substrate 302a which includes a substrate bottom 302F and a substrate top 302B opposite to each other and may include a plurality of trenches 300TRa passing through the dummy substrate 302a. The dummy chip 300c may not include a second bonding insulation layer 392 included in the dummy chip 300a illustrated in FIG. 4. The package molding layer 400a may cover a portion of an upper surface of the first semiconductor chip 100 which is not covered by the second semiconductor chip 200, side surfaces of the plurality of second semiconductor chips 200, and a side surface of the dummy chip 300c and may fill the plurality of trenches 300TRa. A portion, filling the plurality of trenches 300TRa, of the package molding layer 400a may be referred to as a filling molding portion 400TFa.

A second inactive surface 202B of a second semiconductor substrate 202 of the uppermost second semiconductor chip 200Ta may contact a substrate bottom 302F of a dummy substrate 302a of the dummy chip 300c and a lower surface of a filling molding portion 400TFa of the package molding layer 400a. For example, a second inactive surface 202B of a second semiconductor substrate 202 of the uppermost second semiconductor chip 200Ta may all be covered by the substrate bottom 302F of the dummy substrate 302a of the dummy chip 300c and the lower surface of the filling molding portion 400TFa of the package molding layer 400a. The dummy substrate 302a of the dummy chip 300c and the second semiconductor substrate 202 of the uppermost second semiconductor chip 200Ta may configure a covalent bond and may be bonded to each other.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a first semiconductor chip including a first semiconductor substrate and a plurality of first through-electrodes passing through the first semiconductor substrate, the first semiconductor substrate including a first active surface and a first inactive surface opposite to the first active surface;
a plurality of second semiconductor chips, each second semiconductor chip of the plurality of second semiconductor chips including a second semiconductor substrate, a plurality of second through-electrodes passing through the second semiconductor substrate, the second semiconductor substrate including a second active surface and a second inactive surface opposite to the second active surface, the second active surface of the second semiconductor substrate facing the first inactive surface of the first semiconductor substrate, and the plurality of second semiconductor chips being stacked on the first semiconductor chip;
a plurality of bonding pads between the first semiconductor chip and the plurality of second semiconductor chips, the plurality of bonding pads electrically connecting the plurality of first through-electrodes to the plurality of second through-electrodes;
a dummy chip including a dummy substrate having a substrate top surface and a substrate bottom surface opposite to the substrate top surface, the substrate bottom surface of the dummy substrate facing an uppermost second semiconductor chip of the plurality of second semiconductor chips, and the dummy chip being attached to the plurality of second semiconductor chips; and
a package molding layer on the first semiconductor chip and covering an upper surface of the first semiconductor chip, side surfaces of the plurality of second semiconductor chips, and a side surface of the dummy chip,
wherein the dummy chip comprises a plurality of trenches receiving a filling molding portion of the package molding layer and extending into the dummy substrate from a lower surface of the dummy chip.

2. The semiconductor package of claim 1, wherein the plurality of trenches extend toward an inner portion of the dummy chip from a side surface of the dummy chip.

3. The semiconductor package of claim 1, wherein the plurality of trenches are connected to each other within the dummy chip.

4. The semiconductor package of claim 1, wherein the plurality of trenches extend from a first side surface of the dummy chip to a second side surface opposite to the first side surface of the dummy chip.

5. The semiconductor package of claim 4, wherein the plurality of trenches are interconnected within the dummy chip.

6. The semiconductor package of claim 1,
wherein the uppermost second semiconductor chip of the plurality of second semiconductor chips comprises a first bonding insulation layer covering the second inactive surface of the second semiconductor substrate, and
wherein the dummy chip comprises a second bonding insulation layer contacting the first bonding insulation layer and covering the substrate bottom surface of the dummy substrate.

7. The semiconductor package of claim 1, wherein the uppermost second semiconductor chip of the plurality of second semiconductor chips comprises a bonding insulation layer contacting the substrate bottom surface of the dummy substrate and covering the second inactive surface of the second semiconductor substrate.

8. The semiconductor package of claim 1,
wherein the dummy chip comprises a bonding insulation layer contacting the second inactive surface of the second semiconductor substrate included in the uppermost second semiconductor chip of the plurality of second semiconductor chips, and
wherein the bonding insulation layer covers the substrate bottom surface of the dummy substrate.

9. The semiconductor package of claim 1, wherein the second inactive surface of the second semiconductor substrate included in the uppermost second semiconductor chip of the plurality of second semiconductor chips contacts the substrate bottom surface of the dummy substrate.

10. The semiconductor package of claim 1, wherein the plurality of trenches pass through the dummy chip from a lower surface of the dummy chip to an upper surface of the dummy chip.

11. A semiconductor package comprising:
a first semiconductor chip including:
a first semiconductor substrate having a first active surface and a first inactive surface opposite to the first active surface,
a plurality of first through-electrodes passing through the first semiconductor substrate,
a plurality of package connection pads connected to the plurality of first through-electrodes on the first active surface of the first semiconductor substrate,
a first front insulation layer surrounding the plurality of package connection pads on the first active surface of the first semiconductor substrate, and
a first backside insulation layer covering the first inactive surface of the first semiconductor substrate;
a plurality of second semiconductor chips, each second semiconductor chip of the plurality of second semiconductor chips including:
a second semiconductor substrate having a second active surface and a second inactive surface opposite to the second active surface,
a plurality of second through-electrodes passing through the second semiconductor substrate,
a second front insulation layer on the second active surface of the second semiconductor substrate, and
a second backside insulation layer covering the second inactive surface of the second semiconductor substrate, the second active surface of the second semiconductor substrate facing the first inactive surface of the first semiconductor substrate, and the plurality of second semiconductor chips being stacked on the first semiconductor chip;
a plurality of first bonding pads between the first semiconductor chip and a lowermost second semiconductor chip of the plurality of second semiconductor chips, the plurality of first bonding pads electrically connecting the plurality of first through-electrodes of the first semiconductor chip to the plurality of second through-electrodes of the lowermost second semiconductor chip, the plurality of first bonding pads passing through the first backside insulation layer of the first semiconductor chip and the second front insulation layer of the lowermost second semiconductor chip of the plurality of second semiconductor chips;
a plurality of second bonding pads between two second semiconductor chips of the plurality of second semiconductor chips, the two second semiconductor chips being adjacent to each other in a vertical direction, the plurality of second bonding pads electrically connecting the plurality of second through-electrodes of each of the plurality of second through-electrodes of the two second semiconductor chips, the plurality of second bonding pads passing through a second backside insulation layer of a lower second semiconductor chip and a second front insulation layer of an upper second semiconductor chip among the two second semiconductor chips adjacent to each other in the vertical direction;
a dummy chip including a dummy substrate having a substrate top surface and a substrate bottom surface opposite to the substrate top surface, the substrate bottom surface of the dummy substrate facing an uppermost second semiconductor chip of the plurality of second semiconductor chips, and the dummy chip being attached to the plurality of second semiconductor chips; and
a package molding layer on the first semiconductor chip, the package molding layer covering an upper surface of the first semiconductor chip, side surfaces of the plurality of second semiconductor chips, and a side surface of the dummy chip,
wherein the dummy chip comprises a plurality of trenches receiving a filling molding portion of the package molding layer, the plurality of trenches extending into the dummy substrate from a side surface of the dummy chip and extending into the dummy substrate from a lower surface of the dummy chip.

12. The semiconductor package of claim 11,
wherein at least one first trench of the plurality of trenches extends in a first horizontal direction from a first side surface of the dummy chip to a second side surface of the dummy chip that is opposite to the first side surface in the first horizontal direction, and
wherein at least one second trench of the plurality of trenches extends in a second horizontal direction perpendicular to the first horizontal direction from a third side surface of the dummy chip to a fourth side surface of the dummy chip that is opposite to the third side surface of the dummy chip in the second horizontal direction, the at least one second trench being connected to the at least one first trenches of the plurality of trenches.

13. The semiconductor package of claim 11, wherein the plurality of trenches are spaced apart from one another in the dummy chip and extend in a horizontal direction from a first side surface of the dummy chip to a second side surface of the dummy chip that is opposite to the first side surface of the dummy chip in the horizontal direction.

14. The semiconductor package of claim 11, wherein the dummy chip comprises a bonding insulation layer contacting the second backside insulation layer of the uppermost second semiconductor chip and covering the substrate bottom surface of the dummy substrate.

15. The semiconductor package of claim 14, wherein the plurality of trenches pass through the bonding insulation layer.

16. The semiconductor package of claim 11,
wherein the plurality of trenches pass through the dummy chip from a lower surface of the dummy chip to an upper surface of the dummy chip, and
wherein the dummy substrate comprises a plurality of substrate isolators spaced apart from one another in a horizontal direction by the plurality of trenches.

17. The semiconductor package of claim 11,
wherein an upper surface of the first backside insulation layer of the first semiconductor chip contacts a lower surface of the second front insulation layer of the lowermost second semiconductor chip of the plurality of second semiconductor chips, and
wherein an upper surface of a second backside insulation layer of a lower second semiconductor chip of the two second semiconductor chips adjacent to each other in the vertical direction contacts a lower surface of a second front insulation layer of an upper second semiconductor chip of the two second semiconductor chips.

18. A semiconductor package comprising:
a first semiconductor chip including a first semiconductor substrate having a first active surface and a first inactive surface opposite to the first active surface, a plurality of first through-electrodes passing through the first semiconductor substrate, a plurality of package connection pads connected to the plurality of first through-electrodes on the first active surface of the first semiconductor substrate, a first front insulation layer surrounding the plurality of package connection pads on the first active surface of the first semiconductor substrate, and a first backside insulation layer covering the first inactive surface of the first semiconductor substrate;
a plurality of second semiconductor chips, each second semiconductor chip of the plurality of second semiconductor chips includes a second semiconductor substrate having a second active surface and a second inactive surface opposite to the second active surface, a plurality of second through-electrodes passing through the second semiconductor substrate, a second front insulation layer on the second active surface of the second semiconductor substrate, and a second backside insulation layer covering the second inactive surface of the second semiconductor substrate, the second active surface of the second semiconductor substrate facing the first inactive surface of the first semiconductor substrate, and the plurality of second semiconductor chips being stacked on the first semiconductor chip;
a plurality of first bonding pads between the first semiconductor chip and a lowermost second semiconductor chip of the plurality of second semiconductor chips, the plurality of first bonding pads electrically connecting the plurality of first through-electrodes of the first semiconductor chip to the plurality of second through-electrodes of the lowermost second semiconductor chip, the plurality of first bonding pads passing through the first backside insulation layer of the first semiconductor chip and the second front insulation layer of the lowermost second semiconductor chip of the plurality of second semiconductor chips;
a plurality of second bonding pads between two second semiconductor chips of the plurality of second semiconductor chips, the two second semiconductor chips being adjacent to each other in a vertical direction, the plurality of second bonding pads electrically connecting the plurality of second through-electrodes of each of the plurality of second through-electrodes of the two second semiconductor chips, the plurality of second bonding pads passing through a second backside insulation layer of a lower second semiconductor chip and a second front insulation layer of an upper second semiconductor chip of the two second semiconductor chips adjacent to each other in the vertical direction;
a dummy chip including a dummy substrate having a substrate top surface and a substrate bottom surface opposite to the substrate top surface and a bonding insulation layer covering the substrate bottom surface of the dummy substrate, the bonding insulation layer facing an uppermost second semiconductor chip of the plurality of second semiconductor chips and being attached to the plurality of second semiconductor chips; and
a package molding layer on the first semiconductor chip, the package molding layer covering an upper surface of the first semiconductor chip, side surfaces of the plurality of second semiconductor chips, and a side surface of the dummy chip,
wherein the dummy chip comprises a plurality of trenches receiving a filling molding portion of the package molding layer, the plurality of trenches extending from a first side surface of the dummy chip to a second side surface of the dummy chip, and passing through the substrate bottom surface of the dummy substrate from a lower surface of the bonding insulation layer and extending into the dummy substrate.

19. The semiconductor package of claim 18,
wherein an upper surface of the first backside insulation layer of the first semiconductor chip contacts a lower surface of the second front insulation layer of the lowermost second semiconductor chip of the plurality of second semiconductor chips,
wherein an upper surface of a second backside insulation layer of a lower second semiconductor chip of the two second semiconductor chips adjacent to each other in the vertical direction contacts a lower surface of a second front insulation layer of an upper second semiconductor chip of the two second semiconductor chips, and
wherein an upper surface of the second backside insulation layer of the uppermost second semiconductor chip contacts a lower surface of the bonding insulation layer of the dummy chip.

20. The semiconductor package of claim 18, wherein the substrate top surface of the dummy substrate and an upper surface of the package molding layer form a coplanar surface.
